(19) United States
(12) Patent Application Publication
(10) Pub. No.: US 2026/0333692 A1
(43) Pub. Date: Oct. 22, 2026

(54) SEMICONDUCTOR DEVICES WITH CHANNEL SPACER LAYERS OF DIFFERENT CRYSTALLINE PHASES

(71) Applicant: Samsung Electronics Co., Ltd., Suwon-si (KR)

(72) Inventors: Namsoo Kim, Suwon-si (KR); Sunggil Kim, Suwon-si (KR); Kyengmun Kang, Suwon-si (KR); Siyeong Yang, Suwon-si (KR); Jehong Oh, Suwon-si (KR)

(21) Appl. No.: 19/367,045

(22) Filed: Oct. 23, 2025

(30) Foreign Application Priority Data
Apr. 16, 2025 (KR) 10-2025-0049736

(51) Int. Cl. H10B 43/27; H10B 80/00; H10D 80/30; H10W 90/00; H10W 90/26

(52) U.S. Cl. CPC H10B 43/27; H10B 80/00; H10D 80/30; H10W 90/00; H10W 90/26; H10W 90/792

(57) ABSTRACT

A semiconductor device includes a first semiconductor structure and a second semiconductor structure connected to the first semiconductor structure. The second semiconductor structure includes a conductive layer; a stack structure; an upper interconnection structure; an upper bonding structure; and channel structures extending into the stack structure in the first direction and protruding to an upper surface of the stack structure. Each of the channel structures includes a through-portion and a head portion and each of the channel structures includes a conductive spacer layer; a first buried insulating layer; a channel layer including a folded portion and a channel portion; a second buried insulating layer spaced apart from the first buried insulating layer; and a data storage structure disposed on an external side surface of the channel layer.

### CROSS-REFERENCE TO RELATED APPLICATIONS

This application claims benefit of priority to Korean Patent Application No. 10-2025-0049736 filed on Apr. 16, 2025 in the Korean Intellectual Property Office, the disclosure of which is incorporated herein by reference in its entirety.

### BACKGROUND

A semiconductor device that can store high-capacity data in a data storage system has been required. Accordingly, a method for increasing data storage capacity of a semiconductor device has been researched. For example, a semiconductor device has been developed to include memory cells disposed three-dimensionally, instead of memory cells disposed two-dimensionally.

### SUMMARY

Some example implementations of the present disclosure are to provide a semiconductor device having improved integration density and reliability.

According to example implementations of the present disclosure, a semiconductor device includes a first semiconductor structure including a first substrate, circuit elements on the first substrate, a lower interconnection structure connected to the circuit elements, and a lower bonding structure connected to the lower interconnection structure; and a second semiconductor structure connected to the first semiconductor structure on the first semiconductor structure, wherein the second semiconductor structure includes a conductive layer; a stack structure disposed below the conductive layer and including interlayer insulating layers and gate electrodes stacked in a first direction perpendicular to a lower surface of the conductive layer; an upper interconnection structure below the stack structure; an upper bonding structure connected to the upper interconnection structure and bonded to the lower bonding structure; and channel structures penetrating the stack structure in the first direction and protruding to an upper surface of the stack structure, wherein each of the channel structures includes a through-portion penetrating the stack structure and a head portion protruding to the upper surface of the stack structure, wherein each of the channel structures includes a conductive spacer layer forming an outer region of the head portion and being in contact with the conductive layer; a first buried insulating layer on an internal side surface of the conductive spacer layer; a channel layer disposed in the through-portion and including a folded portion covering a lower surface of the first buried insulating layer and a channel portion extending in the first direction from a lower end of the conductive spacer layer; a second buried insulating layer disposed on an internal side surface of the channel layer and spaced apart from the first buried insulating layer; and a data storage structure on an external side surface of the channel layer.

According to example implementations of the present disclosure, a semiconductor device includes gate electrodes stacked and spaced apart from each other in a first direction, the gate electrodes including an uppermost gate electrode; channel structures extending in the first direction by penetrating the gate electrodes, each including a channel layer, a channel filling insulating layer on an internal side surface of the channel layer, a data storage structure on an external side surface of the channel layer, and a conductive spacer layer on the channel layer; and a conductive layer in contact with the conductive spacer layer of the channel structures on the uppermost gate electrode, wherein the channel layer of each of the channel structures includes a channel portion extending in the first direction; and a folded portion bent from the channel portion at a level higher than a level of an upper surface of the uppermost gate electrode and covering an upper end of the channel filling insulating layer, and wherein, in a planar view parallel to a lower surface of the conductive layer, a minimum width of the channel layer is greater than a minimum width of the conductive spacer layer and is less than a maximum width of the conductive spacer layer.

According to example implementations of the present disclosure, a data storage system includes a semiconductor storage device including a first semiconductor structure including a substrate and circuit elements on the substrate, a second semiconductor structure on the first semiconductor structure, and input/output pads electrically connected to the circuit elements; and a controller electrically connected to the semiconductor storage device through the input/output pads and controlling the semiconductor storage device, wherein the second semiconductor structure includes a conductive layer; a stack structure below the conductive layer, and including interlayer insulating layers and gate electrodes stacked in a first direction perpendicular to a lower surface of the conductive layer; and channel structures penetrating the stack structure in the first direction and protruding to an upper surface of the stack structure, wherein each of the channel structures includes a through-portion penetrating the stack structure and a head portion protruding to the upper surface of the stack structure, wherein each of the channel structures includes a conductive spacer layer forming an outer region of the head portion and being in contact with the conductive layer; a first buried insulating layer on an internal side surface of the conductive spacer layer; a channel layer disposed in the through-portion and including a folded portion covering a lower surface of the first buried insulating layer and a channel portion extending in the first direction from a lower end of the conductive spacer layer; a second buried insulating layer disposed on an internal side surface of the channel layer and spaced apart from the first buried insulating layer; and a data storage structure disposed on an external side surface of the channel layer.

### BRIEF DESCRIPTION OF DRAWINGS

The above and other aspects, features, and advantages of the present disclosure will be more clearly understood from the following detailed description, taken in combination with the accompanying drawings.

FIG. 1A is a plan diagram illustrating a semiconductor device according to example implementations of the present disclosure.

FIG. 1B is a cross-sectional diagram illustrating a semiconductor device according to example implementations of the present disclosure.

FIG. 1C is an enlarged cross-sectional diagram illustrating a portion of a semiconductor device according to example implementations of the present disclosure.

FIG. 1D is enlarged plan diagrams illustrating a portion of a semiconductor device according to example implementations of the present disclosure.

FIG. 2A is an enlarged cross-sectional diagram illustrating a portion of a semiconductor device according to example implementations of the present disclosure.

FIG. 2B is plan diagrams illustrating a portion of a semiconductor device according to example implementations of the present disclosure.

FIG. 3 is an enlarged cross-sectional diagram illustrating a portion of a semiconductor device according to example implementations of the present disclosure.

FIG. 4 is an enlarged cross-sectional diagram illustrating a portion of a semiconductor device according to example implementations of the present disclosure.

FIG. 5A is a cross-sectional diagram illustrating a semiconductor device according to example implementations of the present disclosure.

FIG. 5B is a cross-sectional diagram illustrating a portion of a semiconductor device according to example implementations of the present disclosure.

FIG. 6 is a flowchart illustrating a method of manufacturing a semiconductor device according to example implementations of the present disclosure.

FIG. 7 is a flowchart illustrating a method of manufacturing a semiconductor device according to example implementations of the present disclosure.

FIGS. 8, 9A, 10A, 11A, 12A, 13A, 14A, 15A, 16, 17A, 18, 19, 20 and 21A are enlarged cross-sectional diagrams illustrating processes of a method of manufacturing a semiconductor device in order according to example implementations of the present disclosure.

FIGS. 9B, 10B, 11B, 12B, 13B, 14B, 15B, 17B and 21B are enlarged cross-sectional diagrams illustrating processes of a method of manufacturing a semiconductor device in order according to example implementations of the present disclosure.

FIG. 22 is a diagram illustrating a data storage system including a semiconductor device in example implementations of the present disclosure.

FIG. 23 is a perspective diagram illustrating a data storage system including a semiconductor device in example implementations of the present disclosure.

### DETAILED DESCRIPTION

Hereinafter, implementations of the present disclosure will be described as follows with reference to the accompanying drawings.

In example implementations, the terms such as “upper,” “upper portion,” “upper surface,” “above,” “lower,” “lower portion,” “lower surface,” “below, ”“side surface,” or the like, may be referred to based on the drawings unless otherwise indicated. The “upper end” of an element indicates the portion positioned at the highest level based on the drawing, and the “lower end” of an element indicates the portion positioned at the lowest level based on the drawing. “Level” indicates the position disposed in the vertical direction (Z-direction) based on the drawing, and the higher the element is positioned in the vertical direction, the higher the level may be.

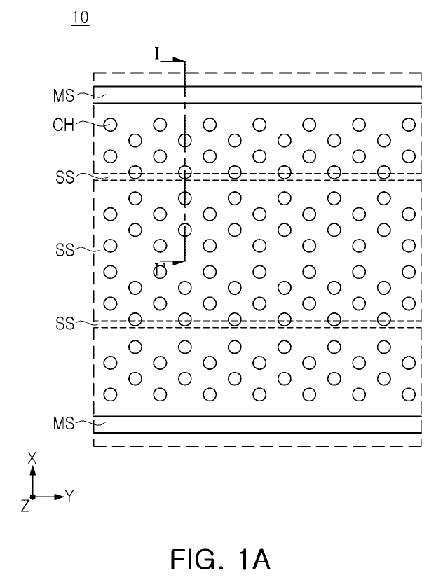

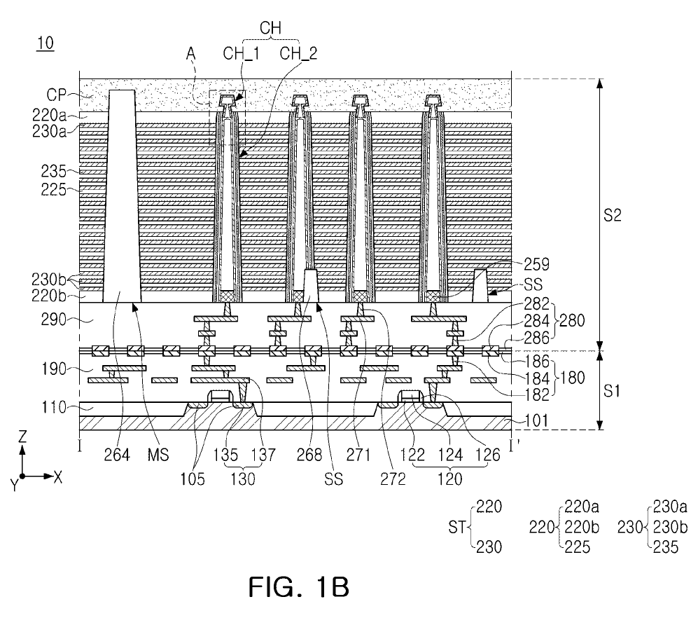

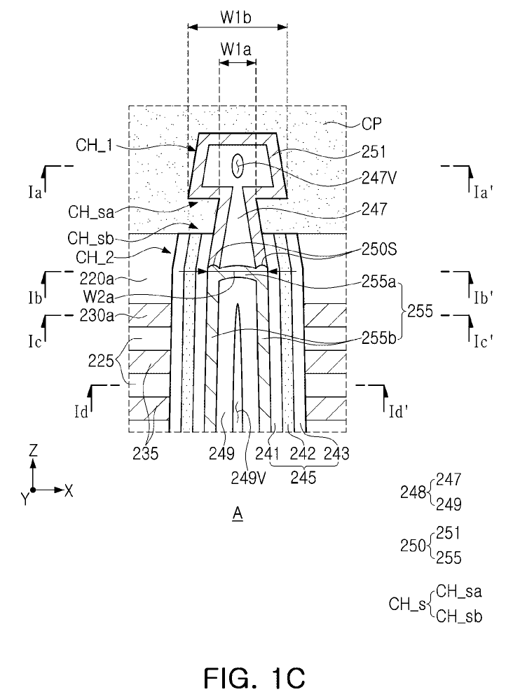

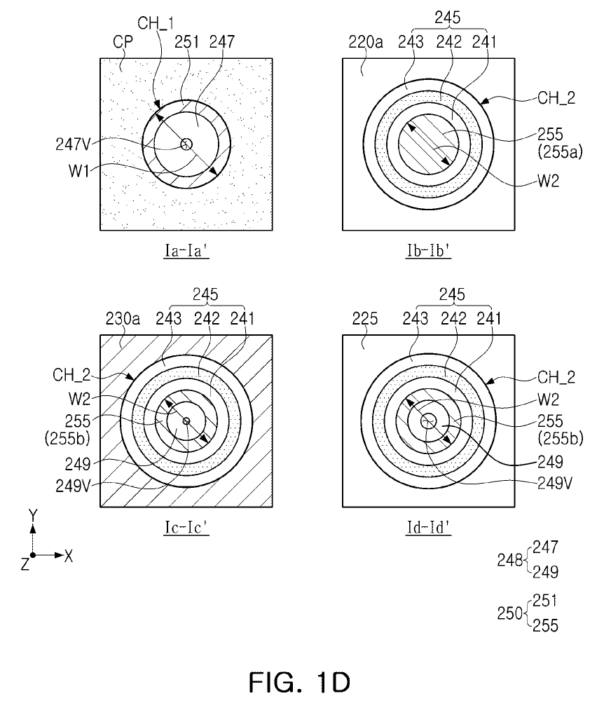

FIG. 1A is a plan diagram illustrating a semiconductor device according to example implementations, illustrating a portion of elements of the semiconductor device.

FIG. 1B is a cross-sectional diagram illustrating a semiconductor device according to example implementations, taken along line I-I’ in FIG. 1A;

FIG. 1C is an enlarged cross-sectional diagram illustrating a portion of a semiconductor device according to example implementations, illustrating region “A” in FIG. 1B.

FIG. 1D is enlarged plan diagrams illustrating a portion of a semiconductor device according to example implementations, taken along lines Ⅰa-Ⅰa’, Ⅰb-Ⅰb’, Ⅰc-Ⅰc’ and Ⅰd-Ⅰd’ in FIG. 1C.

When semiconductor devices are integrated, defects such as breakage of the head portion CH_1 of channel structures CH or isolation from the through-portion CH_2 may occur during the process. As channel structures CH in some example implementations include a conductive spacer layer 251 and a channel layer 255 having different crystal structures, defects occurring in the head portion CH_1 during the process may be prevented, thereby providing a semiconductor device having improved reliability and integration density and a data storage system including the same. A detailed description thereof will be described later in the description of each element and the description of the manufacturing method.

Referring to FIGS. 1A, 1B, 1C and 1D, a semiconductor device 10 may include a first semiconductor structure S1 and a second semiconductor structure S2, and the first semiconductor structure S1 may be stacked in the Z-direction, which may be a vertical direction, with respect to the second semiconductor structure S2. Specifically, the first semiconductor structure S1 may be disposed in a lower portion with respect to the second semiconductor structure S2 in the Z-direction. Alternately, in example implementations, the second semiconductor structure S2 may be disposed in a lower portion of the first semiconductor structure S1.

In example implementations, the semiconductor device 10 may include a peripheral circuit structure PERI (see FIG. 1B) which is a first semiconductor structure S1 on which a peripheral circuit region is formed on a first substrate 101, and a memory cell structure CELL (see FIG. 1B) which is a second semiconductor structure S2 including a conductive layer CP.

In some example implementations, the first semiconductor structure S1 may form a peripheral circuit by forming transistors and metal patterns for wiring the transistors on the first substrate 101. After the peripheral circuit is formed on the first semiconductor structure S1, the second semiconductor structure S2 may be formed, but example implementations thereof are not limited thereto.

The semiconductor device 10 may include a cell region and an extended region disposed in the X-direction. FIG. 1A illustrates a portion of the cell region. The cell region may be a memory cell region in which memory cells are disposed, and channel structures CH may be disposed in the cell region, and the extended region may be a region for electrically connecting the memory cells to the peripheral circuit structures PERI, and to this end, gate electrode layers may extend to different lengths in the cell region, but example implementations thereof are not limited thereto.

The first semiconductor structure S1, which is a peripheral circuit structure, may include a first substrate 101, circuit elements 120 on the first substrate 101, a lower interconnection structure 130, a lower bonding structure 180, and a lower capping layer 190.

The first substrate 101 may include a semiconductor material, for example, a group IV semiconductor, a group III-V compound semiconductor, or a group II-VI compound semiconductor. The first substrate 101 may be provided as a bulk wafer or an epitaxial layer. In the first substrate 101, an active region may be defined by device isolation layers 110. Source/drain regions 105 including impurities may be disposed in a portion of the active region.

Circuit elements 120 may include a transistor. Each of the circuit elements 120 may include a circuit gate dielectric layer 122, a circuit gate electrode 124, a spacer layer 126, and a source/drain region 105. Source/drain regions 105 including impurities may be disposed in the first substrate 101 on both sides of the circuit gate electrode 124. The spacer layers 126 may be disposed on both sides of the circuit gate electrode 124. The circuit gate dielectric layer 122 may include silicon oxide, silicon nitride, or a high-κ material. The circuit gate electrode 124 may include at least one of doped silicon, titanium nitride (TiN), tantalum nitride (TaN), and tungsten nitride (WN), titanium silicon nitride (TiSiN), tantalum silicon nitride (TaSiN), tungsten silicon nitride (WSiN), tungsten (W), copper (Cu), aluminum (Al), molybdenum (Mo), or ruthenium (Ru). For example, the circuit gate electrode 124 may include a doped polycrystalline silicon layer. According to some example implementations, the circuit gate electrode 124 may include two or more multilayers.

The lower interconnection structure 130 may be electrically connected to the circuit gate electrodes 124 and the source/drain regions 105 of the circuit elements 120. The lower interconnection structure 130 may include lower contact plugs 135 and lower interconnection lines 137 having at least one region in the form of a line. A portion of the lower contact plugs 135 may be connected to source/drain regions 105, and the other portion of the lower contact plugs 135 may be connected to the gate electrodes 124. The lower contact plugs 135 may electrically connect the lower interconnection lines 137 disposed at different levels from an upper surface of the first substrate 101. The lower interconnection structure 130 may include a conductive material, for example, tungsten (W), copper (Cu), aluminum (Al), or the like, and each of the elements may further include a diffusion barrier including at least one of titanium (Ti), titanium nitride (TiN), tantalum (Ta), tantalum nitride (TaN), or tungsten nitride (WN). According to example implementations, the number of the lower contact plugs 135 and the lower interconnection lines 137 included in the lower interconnection structure 130 and arrangement thereof may be varied.

The lower bonding structure 180 may be connected to the lower interconnection structure 130. The lower bonding structure 180 may include a lower bonding via 182, a lower bonding pad 184, and a lower bonding insulating layer 186. The lower bonding via 182 may be connected to the lower interconnection structure 130. The lower bonding pad 184 may be connected to the lower bonding via 182. The lower bonding via 182 and the lower bonding pad 184 may include a conductive material, for example, tungsten (W), copper (Cu), aluminum (Al), or the like, and each of the elements may further include a diffusion barrier. The lower bonding insulating layer 186 may also function as a diffusion barrier of the lower bonding pad 184 and may include at least one of silicon oxide, silicon nitride, silicon oxynitride, or silicon oxycarbide. The lower bonding insulating layer 186 may have a thickness less than the thickness of the lower bonding pad 184, but example implementations thereof are not limited thereto. The lower bonding structure 180 may be in direct contact with and bonded or connected to the upper bonding structure 280 by hybrid bonding. For example, the lower bonding pad 184 may be in contact with and coupled to the upper bonding pad 284 by copper-to-copper bonding, and the lower bonding insulating layer 186 may be in contact with and coupled to the upper bonding insulating layer 286 by dielectric-to-dielectric bonding. The lower bonding structure 180, together with the upper bonding structure 280, may provide an electrical connection path between the peripheral circuit structure PERI and S1 and the memory cell structure CELL and S2.

The lower capping layer 190 may be disposed on the first substrate 101 and may cover the circuit elements 120 and the lower interconnection structure 130. The lower capping layer 190 may include a plurality of insulating layers. The lower capping layer 190 may include an insulating material, for example, silicon oxide, silicon nitride, silicon oxynitride, or silicon oxycarbide.

The second semiconductor structure S2, which is a memory cell structure, may include, in the cell region, a memory cell region, a conductive layer CP, a stack structure ST including gate electrodes 230 and interlayer insulating layers 220 alternately stacked on a lower surface of the conductive layer CP, channel structures CH disposed to extend into the stack structure ST, isolation regions MS extending through the gate electrodes 230 and extending in one direction, and insulating regions SS extending into a portion of the gate electrodes 230. The second semiconductor structure S2 may further include studs 272 for electrical connection with the first semiconductor structure S1, upper interconnection lines 271 below the stack structure ST, and an upper bonding structure 280 connected to the upper interconnection lines 271.

In the cell region of the semiconductor device 10 illustrated in FIGS. 1A and 1B, gate electrodes 230 may be stacked and spaced apart from each other in the vertical direction, for example, the Z-direction, and channel structures CH may be disposed. The vertical direction may be defined as the first direction. In the extended region, contact plugs may be disposed on at least one side of the cell region in the X-direction, may be connected to the gate electrodes 230, respectively, and may electrically connect the memory cells to the first semiconductor structure S1.

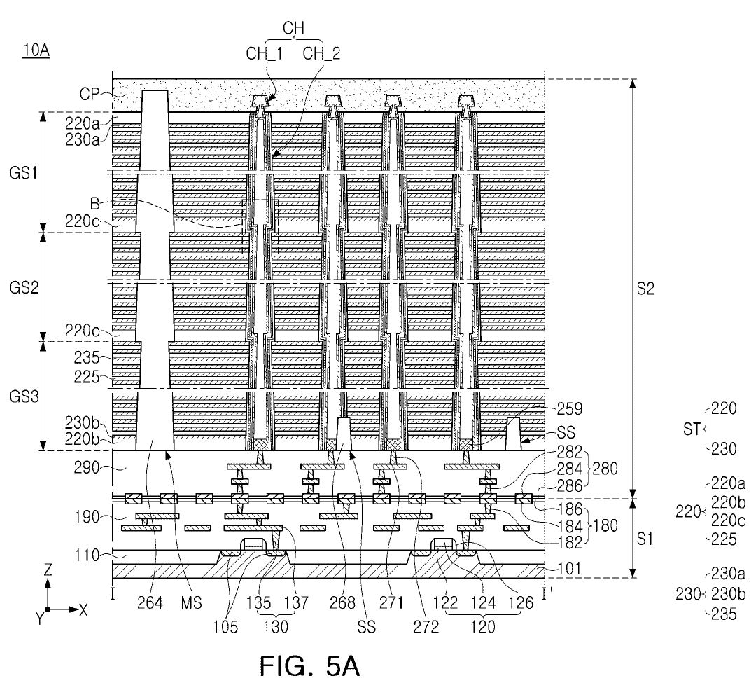

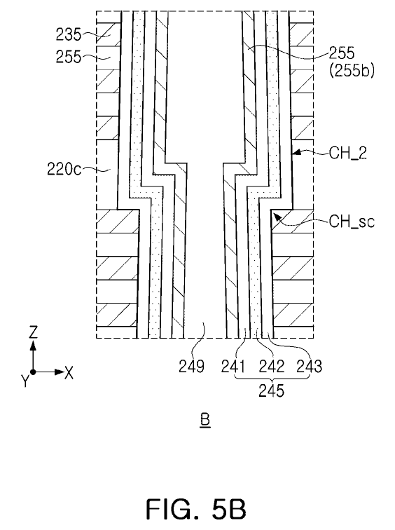

The gate electrodes 230 may be disposed below a lower surface of the conductive layer CP, may be vertically stacked and spaced apart from each other and may form a stack structure ST together with the interlayer insulating layers 220. In some example implementations, the conductive layer CP may be an element formed on the stack structure ST in which the interlayer insulating layers 220 and the gate electrodes 230 are alternately stacked, and a specific description thereof will be described later in the description of the manufacturing method. In FIG. 1B, the stack structure ST may be configured as a single stack structure, but example implementations thereof are not limited thereto. The stack structure ST may include a plurality of stack structures stacked in the vertical direction, which will be described later in the description with reference to FIGS. 5A and 5B.

The gate electrodes 230 may include at least one first gate electrode 230a forming a gate of a ground select transistor, memory gate electrodes 235 forming a plurality of memory cells, and second gate electrodes 230b forming gates of string select transistors. Here, with reference to FIG. 1B, the first gate electrode 230a may be referred to as an upper gate electrode 230a, the second gate electrode 230b may be referred to as a lower gate electrode 230b, and the memory gate electrodes 235 may be referred to as intermediate gate electrodes 235. Among the gate electrodes 230, the gate electrode most adjacent to the conductive layer CP may be referred to as the uppermost gate electrode 230a, and the gate electrode most adjacent to the lower insulating layer 290 may be referred to as the lowermost gate electrode 230b. The number of memory gate electrodes 235 forming the memory cells may be determined depending on a capacity of the semiconductor device 10. In example implementations, the number of each of the upper and lower gate electrodes 230a and 230b may be one to two or more, and may have a structure the same as or different from the memory gate electrodes 235. In some example implementations, the erase gate electrodes may be disposed further below the lower gate electrodes 230b. Also, a portion of the gate electrodes 230, for example, the memory gate electrodes 235 adjacent to the upper or lower gate electrodes 230a and 230b, may be dummy gate electrodes, but example implementations thereof are not limited thereto.

The gate electrodes 230 may be isolated from each other in the X-direction by isolation regions MS extending consecutively in the cell region and the extended region. The gate electrodes 230 between a pair of isolation regions MS may form one memory block BLK, but the range of the memory block BLK is not limited thereto. A portion of the gate electrodes 230, for example, memory gate electrodes 235, may form a layer in each memory block BLK.

The gate electrodes 230 may be stacked and spaced apart from each other vertically in the cell region and the extended region, may extend from the cell region to the extended region by different lengths and may form a portion of the extended region, for example, a step structure having a staircase shape in the extended region, but example implementations thereof are not limited thereto. The gate electrodes 230 may be connected to the contact plugs, respectively.

The gate electrodes 230 may include a metal material, for example, tungsten (W). In example implementations, the gate electrodes 230 may include polycrystalline silicon or a metal silicide material. According to example implementations, the gate electrodes 230 may further include a diffusion barrier, for example, the diffusion barrier may include tungsten nitride (WN), tantalum nitride (TaN), titanium nitride (TiN), or a combination thereof.

The interlayer insulating layers 220 may be disposed between the gate electrodes 230 and may form a stack structure ST. Similarly to the gate electrodes 230, the interlayer insulating layers 220 may be spaced apart from each other in a direction perpendicular to a lower surface of the conductive layer CP and may extend in the X-direction. The interlayer insulating layers 220 may include an insulating material, such as silicon oxide or silicon nitride.

In example implementations, the thicknesses of the interlayer insulating layers 220 may not be the same. For example, among the interlayer insulating layers 220, the first interlayer insulating layer 220a disposed most adjacent to the conductive layer CP and the second interlayer insulating layer 220b disposed most adjacent to the lower insulating layer 290 may have a thickness greater than a thickness of the intermediate interlayer insulating layers 225, but example implementations thereof are not limited thereto. The intermediate interlayer insulating layers 225 may be defined as interlayer insulating layers disposed between the first interlayer insulating layer 220a and the second interlayer insulating layer 220b. The first interlayer insulating layer 220a may be referred to as the uppermost interlayer insulating layer 220a, and the second interlayer insulating layer 220b may be referred to as the lowermost interlayer insulating layer 220b.

The isolation regions MS may be disposed to extend into at least a portion of the gate electrodes 230 and to extend in the Y-direction. The isolation regions MS may be spaced apart from each other in the X-direction and may be disposed in parallel with each other. The isolation regions MS may extend through the entire stacked gate electrodes 230 and may be connected to the lower insulating layer 290. The isolation regions MS may extend as an integrated region in the Y-direction, or may extend intermittently partially, or may be disposed only in a portion of regions.

In the isolation regions MS, an isolation insulating layer 264 may be disposed. The isolation insulating layer 264 may have a shape of which a width decreases toward the conductive layer CP due to a high aspect ratio, but example implementations thereof are not limited thereto. A lower end of the isolation insulating layer 264 may be in contact with the lower insulating layer 290, and an upper end may protrude above an upper surface of the stack structure ST and may be in contact with the conductive layer CP. The width in the X-direction of the upper end of the isolation regions MS may be greater than the width of the upper end of each of the channel structures CH, but example implementations thereof are not limited thereto. The isolation insulating layer 264 may include an insulating material, for example, silicon oxide, silicon nitride, or silicon oxynitride.

The insulating regions SS may extend in the Y-direction between the isolation regions MS adjacent to each other in the X-direction. The insulating regions SS may be disposed in the cell region and may also be disposed partially in the extended region. The insulating regions SS may extend through the second gate electrodes 230b disposed adjacent to the lower insulating layer 290 among the gate electrodes 230. The insulating regions SS may divide the second gate electrode 230b in the X-direction as illustrated in FIG. 1B. It is illustrated that each of the insulating regions SS isolates a plurality of second gate electrodes 230b in FIG. 1B, but the number of second gate electrodes 230b isolated by the insulating regions SS may be varied in example implementations. For example, each of the insulating regions SS may isolate a single second gate electrode 230b.

The insulating regions SS may be disposed by crossing a portion of the channel structures CH. The insulating regions SS may have a predetermined width in the X-direction and may extend to cross the plurality of channel structures CH arranged in a zigzag shape in the Y-direction. Accordingly, when the plurality of channel structures CH are arranged to have the same spacing distance, the insulating regions SS may extend to cross channel structures CH in one row simultaneously. The insulating regions SS may be recessed into a lower end of the channel structures CH, for example, a portion of the channel structures CH opposing the second gate electrodes 230b, and accordingly, a portion of the channel structures CH may be removed. In this case, the channel structures CH may be recessed by a length less than a radius of the channel structures CH from the channel central axis to an internal wall of the channel hole. Accordingly, the insulating regions SS may not pass through the channel central axis of the channel structure CH, and 1/2 or more of the channel structure CH may remain on the lower surface, but example implementations thereof are not limited thereto. The channel structures CH into which the insulating regions SS are recessed into may be effective channel structures actually functioning as memory cells, rather than dummy channel structures. Each of the insulating regions SS may include a lower isolation insulating layer 268. The lower isolation insulating layer 268 may include an insulating material, for example, silicon oxide, silicon nitride, or silicon oxynitride.

The channel structures CH may be spaced apart from each other in rows and columns below the conductive layer CP of the cell region. The channel structures CH may be disposed in a zigzag shape in one direction on the X-Y plane. The channel structures CH may extend into the stack structure ST including the gate electrodes 230 and the interlayer insulating layers 220 in the vertical direction, and may protrude above the stack structure ST and may extend into the conductive layer CP. The channel structures CH may extend in a first direction, for example, in the Z-direction, which is a vertical direction perpendicular to a lower surface of the conductive layer CP, and may have an inclined side surface of which a width decreases toward the conductive layer CP depending on an aspect ratio. That is, the channel structures CH may have an inclined side surface of which a width decreases upwardly.

Each of the channel structures CH may include a through-portion CH_2 extending into the stack structure ST and a head portion CH_1 protruding from an upper portion of the through-portion CH_2. The through-portion CH_2 may be in contact with the gate electrodes 230 and the interlayer insulating layers 220 of the stack structure ST, and the head portion CH_1 may be in contact with the conductive layer CP. Each of the channel structures CH may include bent portions CH_s. The bent portions CH_s may include a first bent portion CH_sa included in the head portion CH_1 and a second bent portion CH_sb between the head portion CH_1 and the through-portion CH2. The bent portions CH_s may be a step difference formed by a width difference or a change of the channel structure CH, and the width of each of the channel structures CH may be varied consecutively in the portions other than the bent portions CH_s. For example, the width of each of the channel structures CH may decrease consecutively toward the conductive layer CP in the portions other than the bent portions CH_s.

The first bent portion CH_sa may be included in the head portion CH_1 and may be positioned at a level overlapping the conductive layer CP. The configuration in which an element is positioned at an overlapping level may indicate that the element overlaps in a direction (e.g., X-direction or Y-direction) perpendicular to the first direction (e.g., Z-direction), which is the vertical direction. In some example implementations, a width of the head portion CH_1 may increase downwardly, other than the first bent portion CH_sa. The width of the head portion CH_1 may discontinuously decrease downwardly with the first bent portion CH_sa as a boundary. The head portion CH_1 may include a step difference formed by a width difference in the first bent portion CH_sa. The head portion CH_1 may have a minimum width at a level the same as or lower than a level of the first bent portion CH_sa, and may have a maximum width at a level the same as or higher than a level of the first bent portion CH_sa. The channel structure CH may have a minimum width in the first bent portion CH_sa of the head portion CH_1. As the head portion CH_1 includes the first bent portion CH_sa, a cross-sectional shape of the head portion CH_1 may be a mushroom shape or an umbrella shape.

The second bent portion CH_sb may be positioned at the lower end of the head portion CH_1 or the upper end of the through-portion CH_2. The second bent portion CH_sb may be positioned at a level lower than a level of the first bent portion CH_sa and at a level higher than a level of the first gate electrode 230a in an uppermost portion. The head portion CH_1 and the through-portion CH_2 may be distinct from each other by the second bent portion CH_sb as a boundary. A width of the channel structure CH may discontinuously decrease upwardly with the second bent portion CH_sb as a boundary. The lower end of the head portion CH_1 and the upper end of the through-portion CH_2 may have a width difference due to the second bent portion CH_sb. The second bent portion CH_sb may be in contact with a lower surface of the conductive layer CP. In some example implementations, the second bent portion CH_sb may be positioned at the same level as an interfacial surface between the conductive layer CP and the first interlayer insulating layer 220a. In some example implementations, the second bent portion CH_sb may be coplanar with a lower surface of the conductive layer CP or an upper surface of the first interlayer insulating layer 220a.

Each of the channel structures CH may include a data storage structure 245, a buried insulating layer 248, a conductive structure 250, and a channel pad 259. The buried insulating layer 248 may include a first buried insulating layer 247 and a second buried insulating layer 249. The conductive structure 250 may include a conductive spacer layer 251 and a channel layer 255.

The conductive structure 250 may be disposed entirely in the head portion CH_1 and the through-portion CH_2 of the channel structure CH, and may be disposed from the upper end of the head portion CH_1 to the lower end of the through-portion CH_2. The conductive structure 250 may include a conductive spacer layer 251 included in the outer region of the head portion CH_1 and a channel layer 255 disposed in the through-portion CH_2.

The conductive spacer layer 251 and the channel layer 255 may include the same semiconductor material such as silicon, and may have different crystal states. Since the conductive spacer layer 251 and the channel layer 255 are formed in separate processes, the conductive spacer layer 251 and the channel layer 255 may have different crystal states even when including the same semiconductor material. In example implementations, “having different crystal states” may indicate that there may be difference in whether the state is a crystalline or amorphous state, whether the state is a monocrystalline or polycrystalline state, a difference in grain size, or the like. In some example implementations, the conductive spacer layer 251 and the channel layer 255 may have a crystalline structure, the conductive spacer layer 251 may include a material of a polycrystalline structure, and the channel layer 255 may include a material of a monocrystalline structure. For example, the conductive spacer layer 251 may include polycrystalline silicon, and the channel layer 255 may include monocrystalline silicon. In some example implementations, a grain size of a material included in the crystalline conductive spacer layer 251 may be different from a grain size of a material included in the crystalline channel layer 255. In some example implementations, the grain size of the material included in the conductive spacer layer 251 may be less than the grain size of the material included in the channel layer 255. For example, the average grain size of the material included in the channel layer 255 may be at least five times greater than the average grain size of the material included in the conductive spacer layer 251. In some example implementations, the conductive spacer layer 251 may include a material having an amorphous structure, and the channel layer 255 may include a material having a crystalline structure. For example, the conductive spacer layer 251 may include amorphous silicon, and the channel layer 255 may include crystalline silicon. According to a difference in crystal state between the conductive spacer layer 251 and the channel layer 255, a channel interfacial surface 250s may be formed. The channel interfacial surface 250s may be positioned at a level overlapping the first interlayer insulating layer 220a. “Being positioned at an overlapping level” may indicate that the element overlaps in a horizontal direction (e.g., X-direction or Y-direction) parallel to a lower surface of the conductive layer CP. The channel interfacial surface 250s may be positioned at a level lower than a level of an upper surface of the first interlayer insulating layer 220a and a level higher than a level of a lower surface of the first interlayer insulating layer 220a. The channel interfacial surface 250s may have an outwardly curved shape, curved toward the conductive spacer layer 251, and a portion of the conductive spacer layer 251 in contact with the channel layer 255 may have an inwardly curved shape.

The conductive spacer layer 251 may form an outer region of the head portion CH_1 and may be in contact with the conductive layer CP. A portion of a lower portion of the conductive spacer layer 251 may extend into the through-portion CH_2 and may be in contact with the data storage structure 245 and the channel layer 255. An external side surface of the conductive spacer layer 251 may be in contact with the conductive layer CP, and an internal side surface of the conductive spacer layer 251 may be in contact with the first buried insulating layer 247. A side surface of the conductive spacer layer 251 may have a step difference due to the first bent portion CH_sa. Referring to FIG. 1D, in a planar view parallel to a lower surface of the conductive layer CP, for example, in view of an X-Y plane, at least a portion of the conductive spacer layer 251 may have an annular shape surrounding the first buried insulating layer 247. In some example implementations, the conductive spacer layer 251 may have a shape such as a cylindrical shape or a prism shape at a level lower than a level of the first bent portion CH_sa without the first buried insulating layer 247, and may have a shape such as a truncated cone shape or a truncated pyramid shape at a level higher than a level of the first bent portion CH_sa. In a planar view, the first width W1 of the conductive spacer layer 251 may be varied depending on the level. The first width W1 of the conductive spacer layer 251 may be defined as a distance between corresponding external side surfaces of the conductive spacer layer 251 in a horizontal direction. The first width W1 of the conductive spacer layer 251 may increase downwardly in a portion other than the first bent portion CH_sa. The first width W1 of the conductive spacer layer 251 may have a minimum width W1a and a maximum width W2b in a portion having the first bent portion CH_sa. The first bent portion CH_sa may be a step difference due to a difference between the minimum width W1a and the maximum width W1b. The maximum width W1b of the conductive spacer layer 251 may be greater than the minimum width W2a of the channel layer 255 and may be less than the maximum width of the channel layer 255. The minimum width W1a of the conductive spacer layer 251 may be less than the minimum width W2a of the channel layer 255. An upper portion of the conductive spacer layer 251 may cover an upper surface of a first buried insulating layer 247, and a planar shape of a portion of the conductive spacer layer 251 covering an upper surface of the first buried insulating layer 247 may be one of a circular shape, an oval shape, and a polygonal shape. A lower end of the conductive spacer layer 251 may be in contact with the channel layer 255, and the lower end of the conductive spacer layer 251 may be positioned at a level overlapping the first interlayer insulating layer 220a. Since the conductive spacer layer 251 is formed by a process different from a process of forming the channel layer 255, the conductive spacer layer 251 may be controlled to not completely fill the space of the head portion CH_1, and the space in which the first buried insulating layer 247 is formed may be stably ensured. Also, when the channel layer 255 is crystallized through a metal induced lateral crystallization (MILC) process, metal particles which may remain may be blocked from diffusing into the conductive spacer layer 251 in example implementations. Accordingly, the head portion CH_1 may be prevented from being broken or isolated during the process, such that a semiconductor device having improved reliability and integration density and a manufacturing method thereof may be provided. The description thereof will be provided later in the description of the manufacturing method.

The channel layer 255 may include a folded portion 255a covering a lower surface of the first buried insulating layer 247 and an upper surface of the second buried insulating layer 249, and a channel portion 255b extending in a vertical direction (e.g., Z-direction) in the through-portion CH_2. The folded portion 255a may be positioned at a level overlapping the first interlayer insulating layer 220a. That is, the folded portion 255a may be positioned at a level lower than a level of an upper surface of the first interlayer insulating layer 220a and higher than a level of a lower surface of the first interlayer insulating layer 220a. The folded portion 255a may be positioned at a level lower than a level of a lower surface of the conductive layer CP. The folded portion 255a may be positioned at a level higher than a level of an upper surface of the first gate electrode 230a. An upper surface of the folded portion 255a may be in contact with the first buried insulating layer 247 and may have an outwardly curved shape toward the first buried insulating layer 247 or the conductive layer CP. A lower surface of the folded portion 255a may be in contact with the second buried insulating layer 249 and may have an inwardly curved shape toward the second buried insulating layer 249. The first buried insulating layer 247 and the second buried insulating layer 249 may be spaced apart from each other by the folded portion 255a. In a planar view, the folded portion 255a may have a circular, elliptical, or polygonal planar shape.

The channel portion 255b may extend in the vertical direction from the lower end of the conductive spacer layer 251 and may extend to the lower end of the channel structure CH. An upper end of the channel portion 255b may be in contact with the conductive spacer layer 251, and a portion of the channel portion 255b in contact with the conductive spacer layer 251 may be included in the channel interfacial surface 250s. In some example implementations, the upper end of the channel portion 255b may be positioned at a level higher than a level of an upper end of the folded portion 255a. A lower end of the channel portion 255b may be positioned at the same level as a lower surface of the second interlayer insulating layer 220b. The channel portion 255b of the channel layer 255 may be formed in an annular shape surrounding the second buried insulating layer 249 therein or may have a columnar shape such as a cylindrical shape or a prism shape without the second buried insulating layer 249 in example implementations. In some example implementations, when the channel layer 255 is crystallized by a metal induced lateral crystallization (MILC) process, a portion of metal particles used may remain in the channel layer 255 in example implementations. In some example implementations, metal particles such as nickel (Ni), titanium (Ti), cobalt (Co), tungsten (W), platinum (Pt), or palladium (Pd) may remain in the channel layer 255. However, even in this case, the metal particles may be prevented from diffusing into the conductive spacer layer 251, and the conductive spacer layer 251 may not include the metal particles. Accordingly, a semiconductor device having improved reliability and integration density and a method of manufacturing the same may be provided, and the relevant description will be described later in the description of the manufacturing method.

In a planar view, the second width W2 of the channel layer 255 may be varied depending on a level. The second width W2 of the channel layer 255 may be defined as a distance between external side surfaces of the corresponding channel portions 255b in a horizontal direction. The second width W2 of the channel layer 255 may increase downwardly. In some example implementations, the portion of the channel layer 255 having the minimum width W2a may be positioned at a level overlapping the folded portion 255a. The minimum width W2a of the channel layer 255 may be greater than the minimum width W1a of the conductive spacer layer 251 and may be less than the maximum width W1b of the conductive spacer layer 251. In some example implementations, the maximum width of the channel layer 255 may be greater than the maximum width W1b of the conductive spacer layer 251. In some example implementations, the maximum width of the channel layer 255 may be less than the maximum width W1b of the conductive spacer layer 251.

Channel pads 259 may be disposed in a lower portion of the channel layer 255 in the channel structures CH. The channel pads 259 may cover a lower surface of the second buried insulating layer 249 and may be electrically connected to the channel layer 255. The channel pads 259 may include, for example, doped polycrystalline silicon.

The buried insulating layer 248 may fill the channel structure CH. The buried insulating layer 248 may include a first buried insulating layer 247 surrounded by an internal side surface of the conductive spacer layer 251 and an upper surface of the folded portion 255a of the channel layer 255 and a second buried insulating layer 249 on a lower surface of the folded portion 255a of the channel layer 255 and the internal side surface of the channel portion 255b. The first buried insulating layer 247 may be referred to as a spacer buried insulating layer 247, and the second buried insulating layer 249 may be referred to as a channel filling insulating layer 249. The first buried insulating layer 247 and the second buried insulating layer 249 may be spaced apart from each other by the folded portion 255a of the channel layer 255. A portion of the first buried insulating layer 247 may be positioned in the head portion CH_1 of the channel structure CH, and the other portion may be positioned in the through-portion CH_2 of the channel structure CH. The first buried insulating layer 247 may cover an internal side surface of the conductive spacer layer 251 and an upper surface of the folded portion 255a of the channel layer 255. The second buried insulating layer 249 may be disposed in the through-portion CH_2. The second buried insulating layer 249 may cover a lower surface of the folded portion 255aand an internal side surface of the channel portion 255b. The first buried insulating layer 247 and the second buried insulating layer 249 may include an insulating material. For example, the first buried insulating layer 247 and the second buried insulating layer 249 may include at least one of silicon oxide, silicon nitride, silicon oxynitride, or silicon oxycarbide. In some example implementations, the first buried insulating layer 247 and the second buried insulating layer 249 may include the same material. In some example implementations, the first buried insulating layer 247 and the second buried insulating layer 249 may include different materials. In some example implementations, a first void 247V may be present in the first buried insulating layer 247. The first void 247V may be spaced apart from the conductive spacer layer 251. The size and the position of the first void 247V and the number of the first void 247V may be varied. A second void 249V may be present in the second buried insulating layer. The second void 249V may be spaced apart from the channel layer 255. The size and the position of the second void 249V and the number of the second void 249V may be varied.

The data storage structure 245 may be disposed between the gate electrodes 230 and the channel layer 255. The data storage structure 245 may extend in the vertical direction on the external side surface of the channel layer 255. The data storage structure 245 may cover at least a portion of the external side surface of the channel layer 255. The data storage structure 245 may cover a portion of the conductive spacer layer 251. The data storage structure 245 may cover the external side surface of the portion in which the conductive spacer layer 251 extends into the through-portion CH_2. An upper end of the data storage structure 245 may be in contact with the conductive layer CP and may form a second bent portion CH_sb. The data storage structure 245 may be formed to cover the entire external side surface of the conductive spacer layer 251 and a portion may be removed during a process, and the second bent portion CH_sb may be formed as a portion of the data storage structure 245 is removed. The data storage structure 245 may include a tunneling layer 241, a charge storage layer 242, and a blocking layer 243 stacked in order from the channel layer 255. The tunneling layer 241 may tunnel electric charge into the charge storage layer 242 and may include, for example, silicon oxide (SiO₂), silicon nitride (Si₃N₄), silicon oxynitride (SiON), or a combination thereof. The charge storage layer 242 may be an electric charge trap layer or a floating gate conductive layer. The blocking layer 243 may include silicon oxide (SiO₂), silicon nitride (Si₃N₄), silicon oxynitride (SiON), a high-κ dielectric material, or a combination thereof. According to example implementations, at least a portion of the data storage structure 245 may form a channel dielectric layer extending in the horizontal direction along the gate electrodes 230.

The conductive layer CP may be disposed on the stack structure ST. In some example implementations, the conductive layer CP may be a plate shape covering the stack structure ST and may be disposed to have flat lower and upper surfaces. The conductive layer CP may be disposed on the first interlayer insulating layer 220a of the stack structure ST, and may be in contact with the first interlayer insulating layer 220a. The conductive layer CP may cover an upper portion of the channel structures CH. The conductive layer CP may cover the head portion CH_1 of the channel structures CH, and may be in contact with a conductive spacer layer 251 included in an outer region of the head portion CH_1. In some example implementations, the conductive layer CP may cover an upper portion of the isolation region MS. In some example implementations, the conductive layer CP may be spaced apart from a portion of the channel structures CH and the isolation region MS, and an insulating pattern may be disposed on the portion. The conductive layer CP may include a semiconductor material. For example, the conductive layer CP may include a semiconductor material, such as a group IV semiconductor, a group III-V compound semiconductor, or a group II-VI compound semiconductor. For example, the group IV semiconductor may include silicon (Si), germanium (Ge), or silicon-germanium (SiGe). The conductive layer CP may function as a common source line (CSL) of the semiconductor device 10. The conductive layer CP may include a silicon layer, for example, a silicon layer having N-type conductivity. For example, the conductive layer CP may be provided by a crystalline semiconductor layer, such as a monocrystalline silicon layer, a polycrystalline silicon layer, or an epitaxial layer doped with impurities. In some example implementations, the conductive layer CP may conformally cover an upper surface of the stack structure ST, an upper portion of the channel structures CH, and an isolation regions MS on the stack structure ST. In some example implementations, the conductive layer CP may include a plurality of conductive layers including different materials. For example, the conductive layer CP may include a first conductive layer covering an upper surface of the stack structure ST, an upper portion of the upper and isolation regions MS of the channel structures CH, and a second conductive layer disposed on the first conductive layer and including a material different from the first conductive layer. The first conductive layer may include a semiconductor material, for example, a group IV compound semiconductor, a group III-V compound semiconductor, or a group II-VI compound semiconductor. For example, the group IV semiconductor may include silicon (Si), germanium (Ge), or silicon-germanium (SiGe). The second conductive layer may include at least one of a metal-semiconductor compound, a metal-nitride, and a metal (e.g., tungsten (W), copper (Cu), aluminum (Al)). The second conductive layer may be aligned perpendicularly to the first conductive layer. The second conductive layer may have a multilayer structure, but example implementations thereof are not limited thereto. For example, the layer structure of the ohmic contact layer, the conductive layer, and the diffusion barrier may be included.

The second semiconductor structure S2 may further include a source contact via and a source interconnection disposed on the conductive layer CP, and may further include a passivation layer protecting the elements.

The upper interconnection structures 271 and 272 may electrically connect the gate electrodes 230 and the channel structures CH to the circuit elements 120. The upper interconnection structures 271 and 272 may include studs 272 connected to the channel structures CH. The studs 272 connected to the channel structures CH may be connected to the channel pads 259 of the channel structures CH. The studs 272 connected to the channel structures CH may be electrically connected to the conductive structures 250 through the channel pads 259 of the channel structures CH in the cell region. The upper interconnection structures 271 and 272 may include a conductive material, for example, tungsten (W), copper (Cu), or aluminum (Al), and each element may further include a diffusion barrier including at least one of titanium (Ti), titanium nitride (TiN), tantalum (Ta), tantalum nitride (TaN), or tungsten nitride (WN). According to example implementations, the number of layers and the arrangement of the studs 272 and the upper interconnection lines 271 included in the upper interconnection structures 271 and 272 may be varied.

The upper bonding structure 280 may be connected to the upper interconnection structures 271 and 272. For example, the studs 272 may be electrically connected to the upper bonding structure 280. The upper bonding structure 280 may include an upper bonding via 282, an upper bonding pad 284, and an upper bonding insulating layer 286. The upper bonding via 282 may be connected to the upper interconnection structure 270. The upper bonding pad 284 may be connected to the upper bonding via 282. The upper bonding via 282 and the upper bonding pad 284 may include a conductive material, for example, tungsten (W), copper (Cu), aluminum (Al), or the like, and each of the elements may further include a diffusion barrier. The upper bonding insulating layer 286 may also function as a diffusion barrier of the upper bonding pad 284, and may include at least one of SiCN, SiO, SiN, SiOC, SiON or SiOCN. The upper bonding insulating layer 286 may have a thickness less than the thickness of the upper bonding pad 284, but example implementations thereof are not limited thereto.

In the description below, any description overlapping the description described with reference to FIGS. 1A, 1B, 1C, and 1D will not be provided.

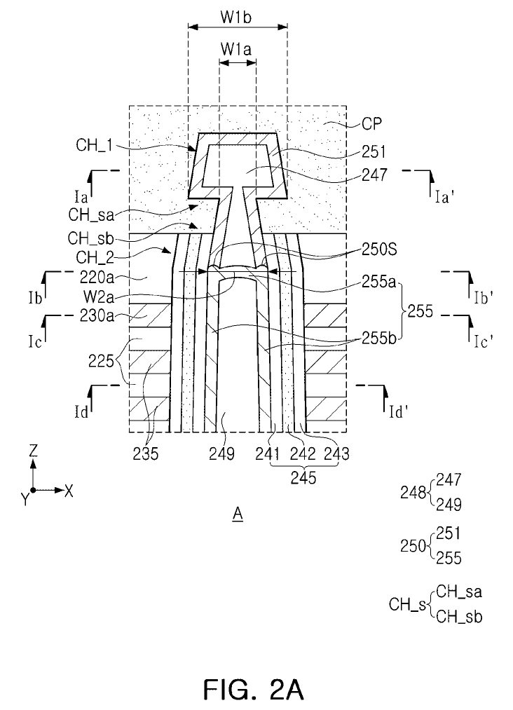

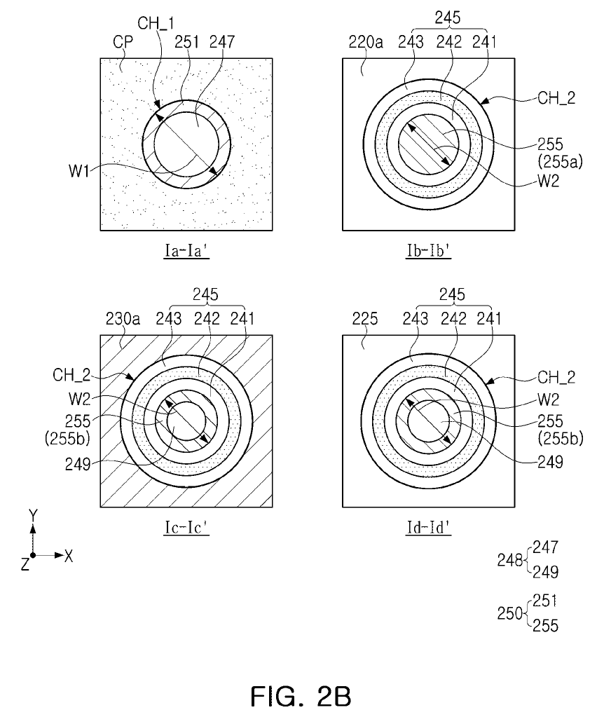

FIG. 2A is an enlarged cross-sectional diagram illustrating a portion of a semiconductor device according to example implementations, illustrating a region corresponding to FIG. 1C.

FIG. 2B is plan diagrams illustrating a portion of a semiconductor device according to example implementations, taken along lines Ⅰa-Ⅰa’, Ⅰb-Ⅰb’, Ⅰc-Ⅰc’ and Ⅰd-Ⅰd’ in FIG. 2A.

Referring to FIGS. 2A and 2B, differently from the example implementations in FIGS. 1C and 1D, voids may not be present in at least a portion of the channel structure CH or may not be visible even when voids may be present. In some example implementations, the first void 247V may be present while the second void 249V may not be present. Conversely, the second void 249V may be present, and the first void 247V may not be present. The presence of the first void 247V and the second void 249V and the number of the first void 247V and the second void 249V and the size thereof may be varied depending on the amount and shape of the filling of the first buried insulating layer 247 and the second buried insulating layer 249.

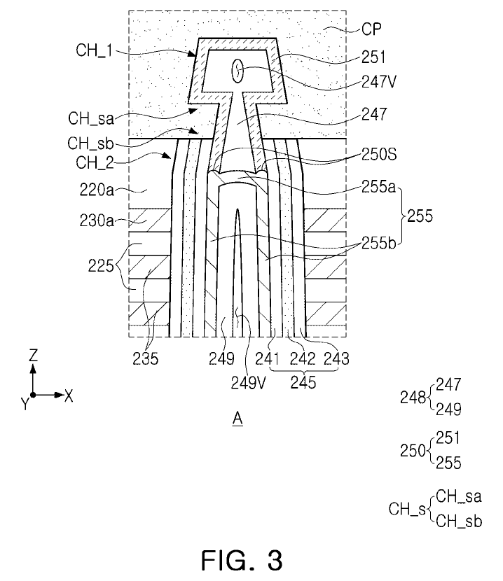

FIG. 3 is an enlarged cross-sectional diagram illustrating a portion of a semiconductor device according to example implementations, illustrating a region corresponding to FIG. 1C.

Referring to FIG. 3, differently from the example implementations in FIG. 1C, the conductive spacer layer 251 may include first conductivity-type impurities. The first conductivity-type impurities may be P-type impurities or N-type impurities. The conductive spacer layer 251 may include silicon doped with first conductivity-type impurities. The conductive layer CP may include first conductivity-type impurities the same as impurities included by the conductive spacer layer 251. For example, when the conductive spacer layer 251 includes N-type impurities such as phosphorus (P), arsenic (As), or antimony (Sb), the conductive layer CP may also include N-type impurities such as phosphorus (P), arsenic (As), or antimony (Sb). Conversely, when the conductive spacer layer 251 includes P-type impurities such as boron (B), the conductive layer CP may also include P-type impurities such as boron (B). The impurities included in the conductive spacer layer 251 may be formed by doping during a process. In some example implementations, the impurities included in the conductive spacer layer 251 may diffuse into the channel layer 255. When the channel layer 255 includes the impurities, a concentration of the first conductivity-type impurities included in the conductive spacer layer 251 may be greater than a concentration of the first conductivity-type impurities included in the channel layer 255. Even when the channel layer 255 includes first conductivity-type impurities, the concentration of the first conductivity-type impurities in the channel layer 255 may be significantly lower than the concentration of the first conductivity-type impurities in the conductive spacer layer 251.

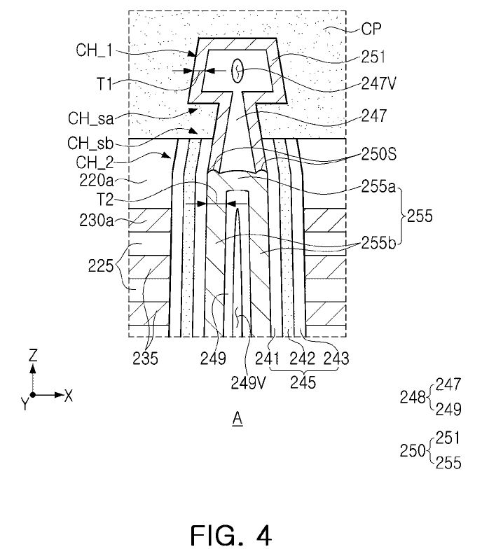

FIG. 4 is an enlarged cross-sectional diagram illustrating a portion of a semiconductor device according to example implementations, illustrating a region corresponding to FIG. 1C.

Referring to FIG. 4, at least a portion of the channel structures CH may have different thicknesses for the conductive spacer layer 251 and the channel layer 255. Since the conductive spacer layer 251 and the channel layer 255 are formed through separate processes, the conductive spacer layer 251 and the channel layer 255 may be formed with different thicknesses. In some example implementations, the first thickness T1 of the conductive spacer layer 251 may be less than the second thickness T2 of the channel layer 255. The conductive spacer layer 251 may be formed to have a relatively thin first thickness T1 to avoid bonding at the first bent portion CH_sa in the head portion CH_1, and the channel layer 255 may be formed to have a relatively thick second thickness T2 to improve functionality.

FIG. 5A is a cross-sectional diagram illustrating a semiconductor device according to example implementations, illustrating a region corresponding to FIG. 1B.

FIG. 5B is a cross-sectional diagram illustrating a portion of a semiconductor device according to example implementations, illustrating region “B” in FIG. 5B.

Referring to FIGS. 5A and 5B, differently from the semiconductor device 10 in FIGS. 1A, 1B, 1C, and 1D, the stack structure ST of the semiconductor device 10a may include a plurality of levels GS1, GS2, and GS3. In some example implementations, the stack structure ST may include three to five levels, and may include, for example, three levels as in FIG. 5A. The interlayer insulating layers 220 may include a third interlayer insulating layer 220c positioned in a lowermost portion of each level. In some example implementations, the third interlayer insulating layer 220c may be formed to have a thickness greater than that of the intermediate insulating layers 225. The channel structures CH may include third bent portions CH_sc due to a difference or a change in width at a boundary of each level. The isolation region MS may include bent portions positioned at the same level as the third bent portions CH_sc.

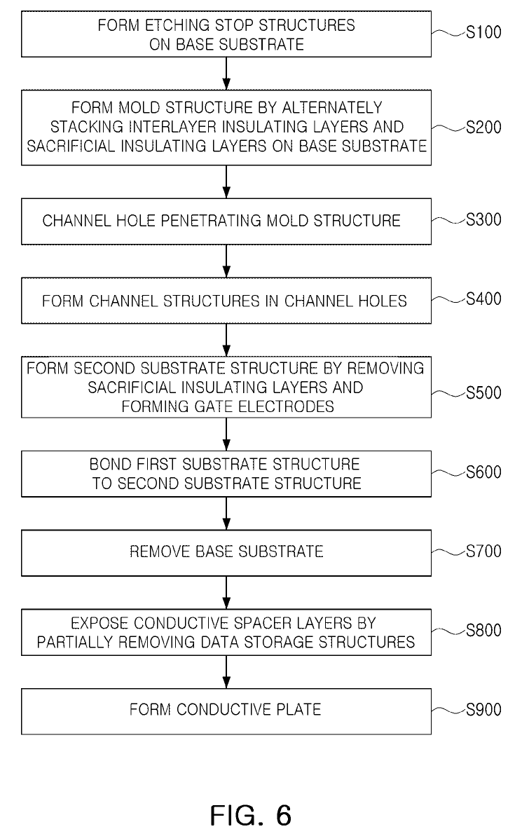

FIG. 6 is a flowchart illustrating a method of manufacturing a semiconductor device according to example implementations.

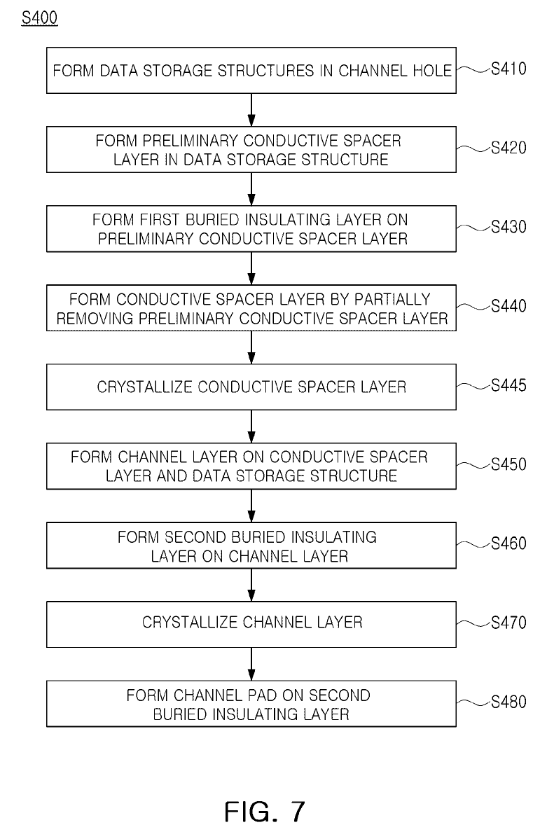

FIG. 7 is a flowchart illustrating a method of manufacturing a semiconductor device according to example implementations, illustrating processes of forming the channel structures CH of FIG. 6 (S400).

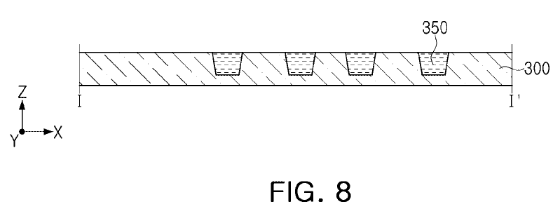

FIGS. 8, 9A, 10A, 11A, 12A, 13A, 14A, 15A, 16, 17A, 18, 19, 20 and 21A are enlarged cross-sectional diagram illustrating processes of a method of manufacturing a semiconductor device in order according to example implementations, illustrating a region corresponding to FIG. 1B.

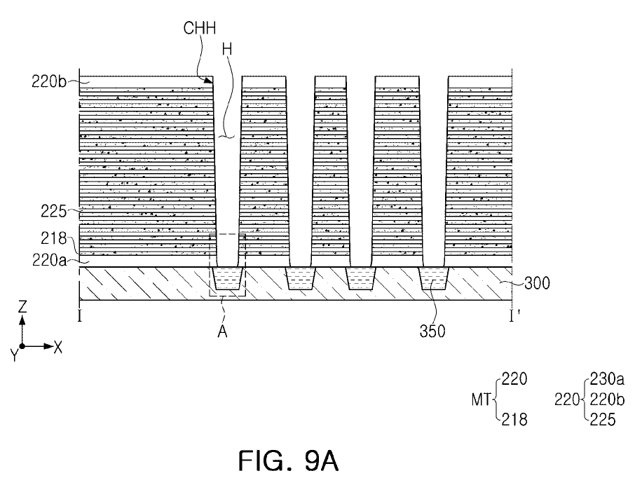

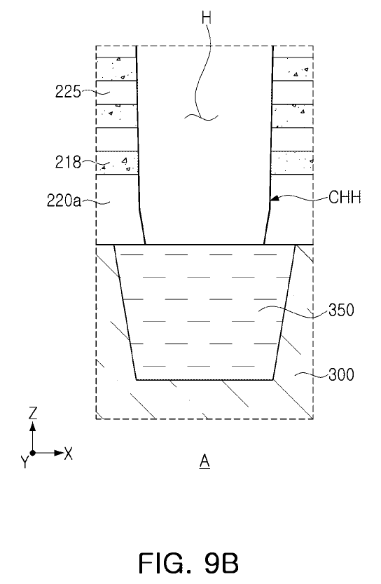

FIGS. 9B, 10B, 11B, 12B, 13B, 14B, 15B, 17B and 21B are enlarged cross-sectional diagram illustrating a portion of processes of a method of manufacturing a semiconductor device in order according to example implementations, illustrating region “A” corresponding to FIG. 1C.

Referring to FIGS. 6 and 8, etching stop structures 350 may be formed on a base substrate 300 (S100).

The base substrate 300 may include a semiconductor material, for example, a group IV semiconductor, a group III-V compound semiconductor, or a group II-VI compound semiconductor.

The etching stop structures 350 may be formed by etching a portion of the base substrate 300 and filling the etching region with an etching stop material. In some example implementations, the etching stop structures 350 may have a width decreasing downwardly. The etching stop structures 350 may include a material having etching selectivity with respect to a material included in a mold structure MT formed in a subsequent process. In some example implementations, the etching stop structures 350 may include tungsten (W). The channel structures CH in FIGS. 1A, 1B, 1C, and 1D may be formed in a region corresponding to the head portion CH_1.

Referring to FIGS. 9A and 9B together with FIG. 6, by alternately stacking interlayer insulating layers 220 and sacrificial insulating layers 218 on a base substrate 300, a mold structure MT may be formed (S200), and a channel hole CHH extending into the mold structure MT may be formed (S300).

At least a portion of the sacrificial insulating layers 218 may be replaced with a portion of gate electrodes 230 through a subsequent process. The sacrificial insulating layers 218 may be formed of a material different from a material of the interlayer insulating layers 220. For example, the interlayer insulating layer 220 may be formed of at least one of silicon oxide or silicon nitride, and the sacrificial insulating layers 218 may be formed of a material other than the interlayer insulating layer 220 selected from among silicon, silicon oxide, silicon carbide, or silicon nitride. In example implementations, the thicknesses of the interlayer insulating layers 220 may not be the same. Also, the thicknesses of the interlayer insulating layers 220 and the sacrificial insulating layers 218 and the number of films included in may be varied from the illustrated example.

The channel holes CHH may be formed by penetrating the mold structure MT on the etching stop structures 350 formed on the base substrate 300 in the vertical direction. The channel holes CHH may be formed by anisotropically etching the mold structure MT using a mask pattern. By the etching stop structures 350, the channel holes CHH may be formed to have a uniform depth.

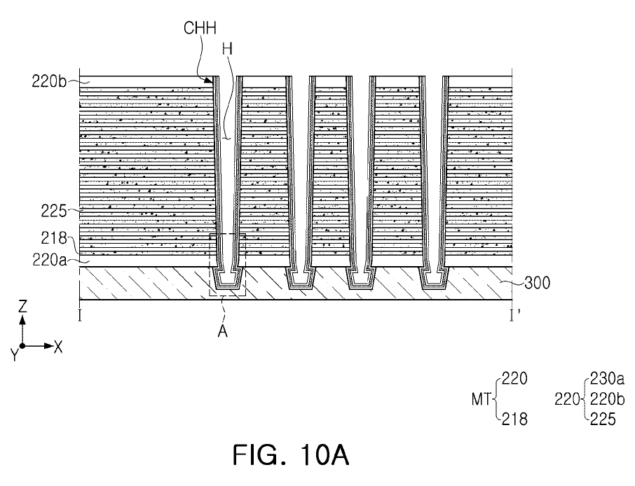

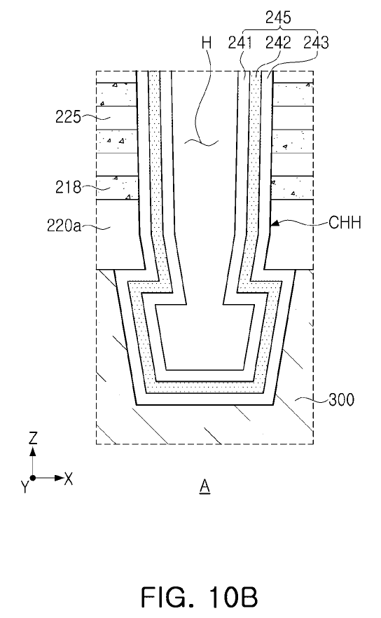

Referring to FIGS. 10A and 10B together with FIGS. 6 and 7, the channel holes CHH may extend by removing the etching stop structures 350, and data storage structures 245 may be formed in the channel holes CHH (S410).

The data storage structures 245 may be formed to have a uniform thickness in the channel holes CHH. The data storage structures 245 may include a plurality of dielectric layers. The data storage structures 245 may be formed by depositing an insulating material including a plurality of layers included in the data storage structures 245 in order in the channel holes CHH.

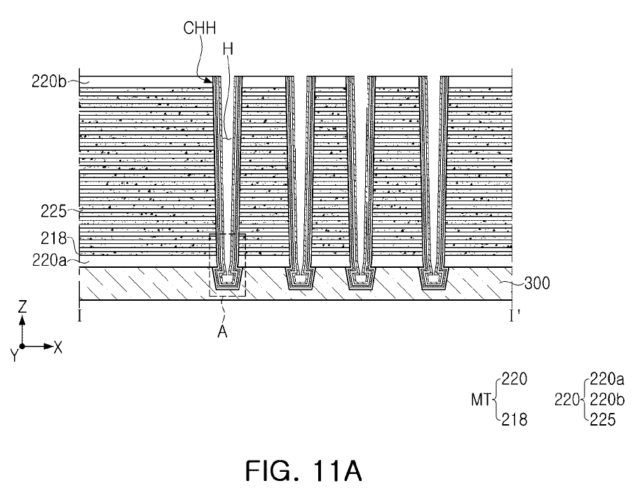

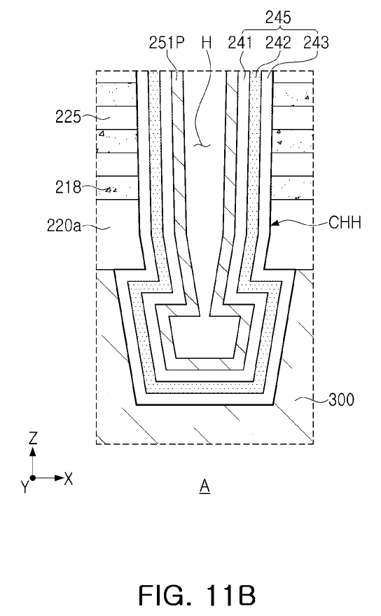

Referring to FIGS. 11A and 11B together with FIGS. 6 and 7, the first semiconductor material layer 251P may be formed by depositing a first semiconductor material on the data storage structures 245 (S420).

The first semiconductor material layer 251P may be formed by depositing a semiconductor material such as polysilicon on the data storage structure 245. The first semiconductor material layer 251P may be formed to cover the data storage structure 245 to have a uniform thickness. By controlling the thickness of the first semiconductor material layer 251P, the hole space H may be maintained to extend into the base substrate 300.

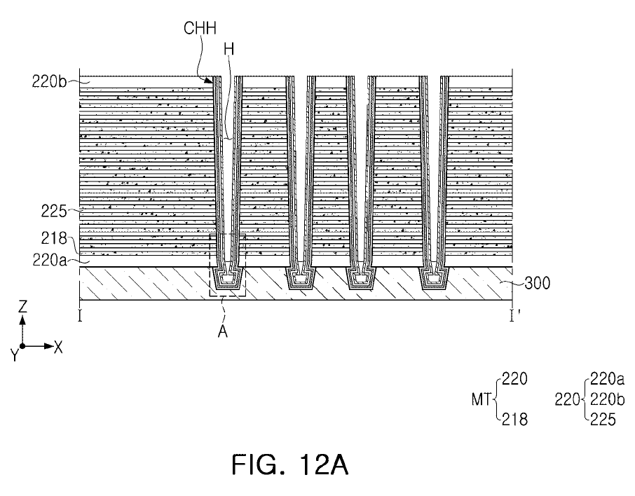

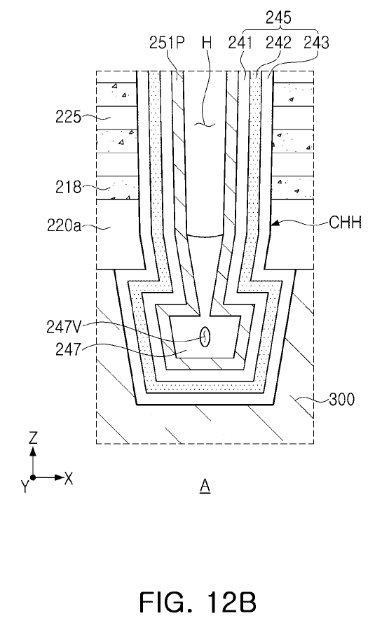

Referring to FIGS. 12A and 12B together with FIGS. 6 and 7, the first buried insulating layer 247 may be formed on the first semiconductor material layer 251P (S430).

The first buried insulating layer 247 may be formed by filling the hole space H in the channel holes CHH with an insulating material, and removing a portion of the formed insulating material downwardly. In some example implementations, the channel holes CHH may be formed to have a width decreasing downwardly, and an insulating material filling the hole space H may be removed from the upper portion and may be etched to a level having a target width. An upper surface of the first buried insulating layer 247 may be formed at a level overlapping the first interlayer insulating layer 220a. That is, an upper surface of the first buried insulating layer 247 may be formed at a level lower than a level of an upper surface of the first interlayer insulating layer 220a and higher than a level of a lower surface of the first interlayer insulating layer 220a.

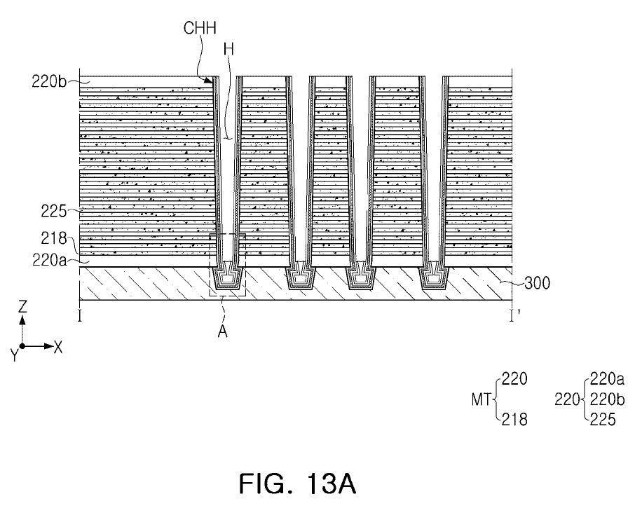

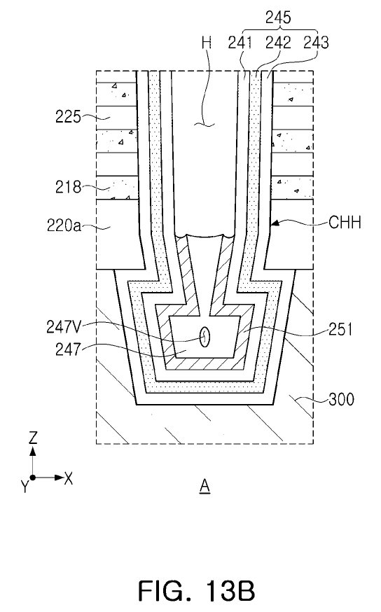

Referring to FIGS. 13A and 13B together with FIGS. 6 and 7, a conductive spacer layer 251 may be formed by partially removing the first semiconductor material layer 251P (S440).

The conductive spacer layer 251 may be formed by partially removing the first semiconductor material layer 251P from an upper portion. The first semiconductor material layer 251P may be removed up to an upper surface of the first buried insulating layer 247. Depending on an etching method of partially removing the first semiconductor material layer 251P from an upper portion, an upper portion of the conductive spacer layer 251 may have an inwardly curved shape. In some example implementations, a crystal state of a material included in the conductive spacer layer 251 may be an amorphous state. In some example implementations, the conductive spacer layer 251 may be crystallized by a process such as annealing (S455), and in this case, the conductive spacer layer 251 may have a crystalline structure. In some example implementations, the annealing process may be performed at 500°C or higher, for example, may be performed at about 600°C. In some example implementations, the process of crystallizing the conductive spacer layer 251 may not be performed.

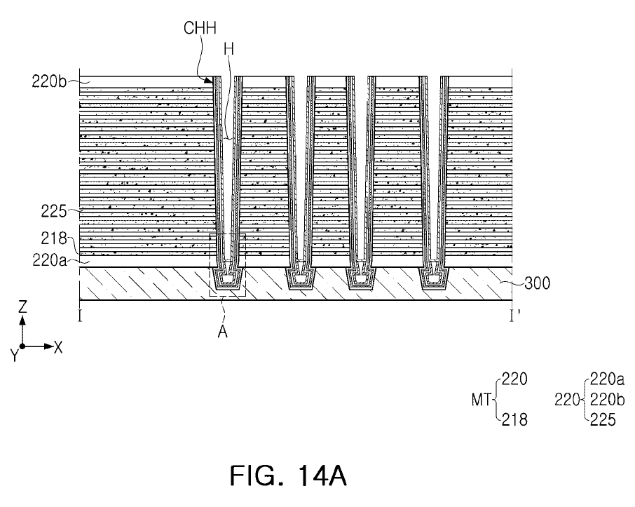

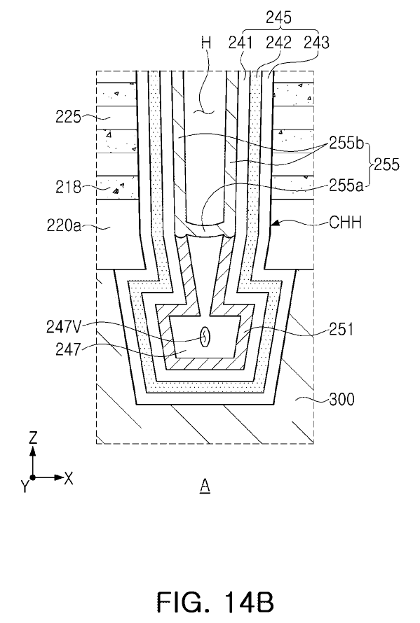

Referring to FIGS. 14A and 14B together with FIGS. 6 and 7, a channel layer 255 may be formed on the conductive spacer layer 251 and the data storage structure 245 (S450).

The channel layer 255 may be formed by depositing a semiconductor material on the conductive spacer layer 251, the first buried insulating layer 247, and the data storage structure 245. The channel layer 255 may be formed to uniformly cover the conductive spacer layer 251, the first buried insulating layer 247, and the data storage structure 245. The channel layer 255 may include a folded portion 255a covering an upper surface of the first buried insulating layer 247 and a channel portion 255b covering the data storage structure 245.

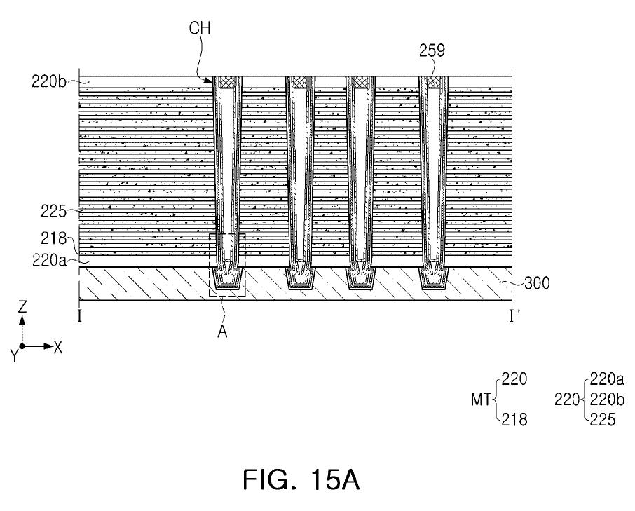

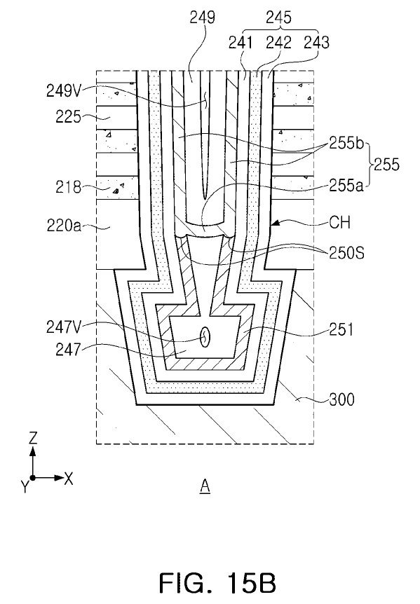

Referring to FIGS. 15A and 15B together with FIGS. 6 and 7, a second buried insulating layer 249 may be formed on the channel layer 255 (S460), the channel layer 255 may be crystallized (S470), and a channel pad (S490) may be formed. Accordingly, the channel structures CH may be formed (S400).

The second buried insulating layer 249 may be formed by filling an insulating material in the hole space H on the channel layer 255. The channel layer 255 may be crystallized by an annealing process or a metal induced lateral crystallization (MILC) process.

In some example implementations, the channel layer 255 may be crystallized by an annealing process. When the channel layer 255 is crystallized by an annealing process, the grain size of the channel layer 255 may be different from the grain size of the conductive spacer layer 251. That is, the channel layer 255 may have a different crystal state from that of the conductive spacer layer 251. When crystallizing the conductive spacer layer 251 (S455) is not performed, the conductive spacer layer 251 may be crystallized together with the channel layer 255 by an annealing process. Even in this case, the conductive spacer layer 251 and the channel layer 255 formed by different processes may have different grain sizes. In some example implementations, the grain size of the channel layer 255 may be greater than the grain size of the conductive spacer layer 251. For example, the grain size of the channel layer 255 may be at least five times greater than the grain size of the conductive spacer layer 251. In some example implementations, the annealing process may be performed at 500°C or higher, for example, at about 600°C.

In some example implementations, the channel layer 255 may be crystallized by a metal induced lateral crystallization (MILC) process. The metal induced lateral crystallization (MILC) process may include, for example, forming a metal layer on an upper portion of the channel layer 255 to be in contact with the channel layer 255, performing a heat treatment on the metal layer to inject metal particles into the channel layer 255, and crystallizing the channel layer 255 from an amorphous state to a crystalline state (in particular, a single crystal state) as the metal particles diffuse along the channel layer 255 toward the base substrate 300. The diffusion of the metal particles crystallizing the channel layer 255 may be performed up to the conductive spacer layer 251 crystallized in the process S455. That is, the metal particles used in the MILC process may remain in the channel layer 255 and may not diffuse into the conductive spacer layer 251. Since the MILC process is performed to crystallize an amorphous state into a crystalline state, the metal particles may be prevented from diffusing into the conductive spacer layer 251 as the crystallization of the conductive spacer layer 251 is preferentially performed (S455). The channel layer 255 may have a monocrystalline or near-monocrystalline structure through the MILC process, and the conductive spacer layer 251 crystallized through the annealing process in process S455 may have a polycrystalline structure. Accordingly, the channel layer 255 and the conductive spacer layer 251 may have different crystal states. The metal layer used in the MILC process may include, for example, nickel (Ni), titanium (Ti), cobalt (Co), tungsten (W), platinum (Pt), palladium (Pd), or a combination thereof, and the metal particles may be at least one of the metals. After crystallizing the channel layer 255 by the MILC process, a gettering process of removing the metal layer and removing the metal particles in the channel layer 255 may be performed. In some example implementations, a trace amount of metal particles may remain in the channel layer 255, but even in this case, the metal particles used in the MILC process may not be present in the conductive spacer layer 251. By preventing the metal particles from remaining in the conductive spacer layer 251, defects such as breakage or isolation of the conductive spacer layer 251 may be prevented in a subsequent process. Since the crystal states of the conductive spacer layer 251 and the channel layer 255 are distinct from each other, a channel interfacial surface 250s may be present therebetween.

The channel pad 259 may be formed on the second buried insulating layer 249 and may be in contact with the channel layer 255. The channel pad 259 may be formed of a conductive material, for example, polycrystalline silicon.

Through the processes in FIGS. 10A, 10B, 11A, 11B, 12A, 12B, 13A, 13B, 14A, 14B, 15A, and 15B, a channel structure CH may be formed in the channel holes CHH (S400).

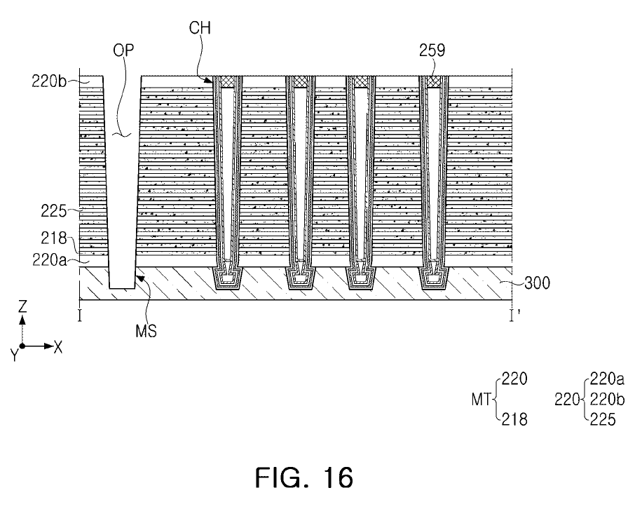

Referring to FIG. 16, isolation openings OP corresponding to isolation regions MS may be formed.

The isolation opening OP may be formed as a line type crossing the cell region and the extended region in the Y-direction and may penetrate the mold structure MT in the Z-direction. The isolation opening OP may be formed to remove a portion of the base substrate 300 and to open a portion of the base substrate 300.

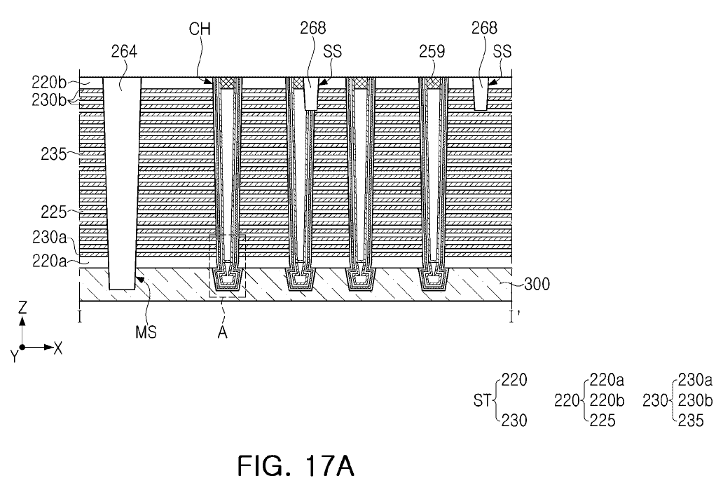

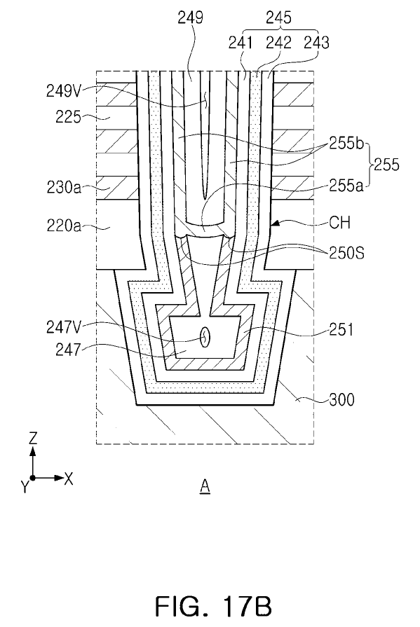

Referring to FIGS. 17A and 17B, the sacrificial insulating layers 218 may be removed, gate electrodes 230 may be formed (S500), and insulating regions SS may be formed.

The sacrificial insulating layers 218 may be selectively removed with respect to the interlayer insulating layers 220 by performing wet etching through the isolation opening OP. The gate electrodes 230 may be formed by depositing a conductive material on the regions from which the sacrificial insulating layers 218 are removed. The conductive material may include a metal, polycrystalline silicon, or a metal silicide material. In some example implementations, a portion of the gate dielectric layer may be formed preferentially before the gate electrodes 230 are formed. After the gate electrodes 230 are formed, isolation insulating layers 264 may be formed in the isolation openings OP formed to correspond to the isolation regions MS, and by etching at least one second gate electrode 230b, insulating regions SS may be formed.

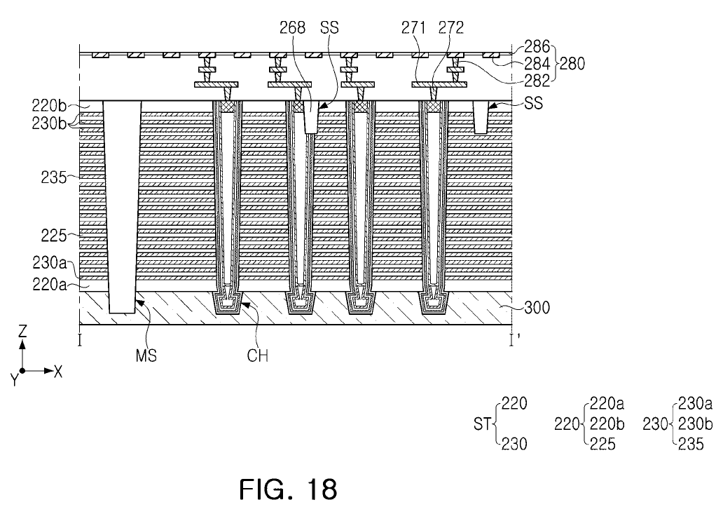

Referring to FIG. 18, upper interconnection structures 271 and 272 including studs 272 and upper interconnection lines 271 may be formed, and an upper bonding structure 280 may be formed.

In the cell region, the studs 272 may be formed to be connected to the channel structures CH. The studs 272 may be vertically connected to the upper interconnection lines 271, respectively, and may be connected in multiple layers through plugs.

Thereafter, the upper bonding structure 280 may be formed by a similar method as the method of forming the lower bonding structure 180. Accordingly, a second semiconductor structure S2, which is a memory cell structure CELL, may be formed. During the manufacturing process of the semiconductor device 10, the second semiconductor structure S2 may be in a state of further including a base substrate 300.

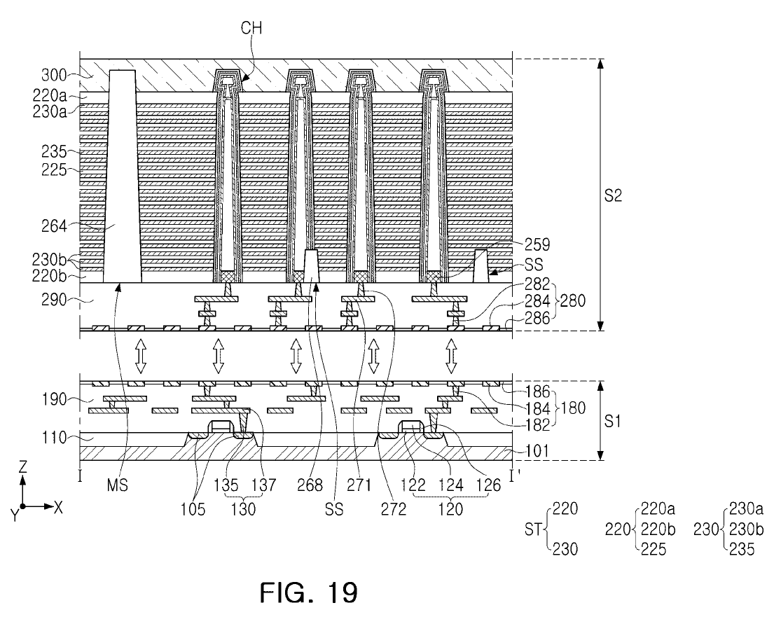

Referring to FIG. 19 together with FIG. 6, the second semiconductor structure S2 may be disposed upside down such that the base substrate 300 is exposed upwardly and may be bonded to the first semiconductor structure S1 (S600).

In example implementations, the sequence of the process for bonding the second semiconductor structure S2 to the first semiconductor structure S1 may be performed after the processes (S700, S800, S900) to be described later. For example, the second semiconductor structure S2 may be bonded to the first semiconductor structure S1 after the conductive layer CP is formed (S900).

The first semiconductor structure S1 may be formed to include circuit elements 120, a lower interconnection structure 130, a lower bonding structure 180, and a lower capping layer 190 forming a peripheral circuit region PERI on the first substrate 101. First, device isolation layers 110 may be formed in the first substrate 101, and a circuit gate dielectric layer 122 and a circuit gate electrode 124 may be formed in order on the first substrate 101. The device isolation layers 110 may be formed, for example, by a shallow trench isolation (STI) process. The circuit gate dielectric layer 122 may be formed on the first substrate 101, and the circuit gate electrode 124 may be formed on the circuit gate dielectric layer 122. The circuit gate dielectric layer 122 and the circuit gate electrode 124 may be formed using atomic layer deposition (ALD) or chemical vapor deposition (CVD). The circuit gate dielectric layer 122 may be formed of silicon oxide, and the circuit gate electrode 124 may be formed of at least one of polycrystalline silicon or a metal silicide layer, but example implementations thereof are not limited thereto. Thereafter, spacer layers 126 may be formed on both sidewalls of the circuit gate dielectric layer 122 and the circuit gate electrode 124, and source/drain regions 105 may be formed by injecting impurities into the active region of the first substrate 101 on both sides of the circuit gate electrode 124.

Lower contact plugs 135 of the lower interconnection structure 130 may be formed by forming a portion of the lower capping layer 190, removing a portion by etching, and filling a conductive material therein. Lower interconnection lines 137 may be formed, for example, by depositing a conductive material and patterning the material.

A lower bonding via 182 of the lower bonding structure 180 may be formed by forming a portion of the lower capping layer 190, removing a portion by etching, and filling a conductive material therein. The lower bonding pad 184 may be formed, for example, by depositing a conductive material and patterning the material. The lower bonding structure 180 may be formed, for example, by a deposition process or a plating process. The lower bonding insulating layer 186 may be formed by covering an upper surface and a portion of a side surface of the lower bonding pad 184, and performing a planarization process until an upper surface of the lower bonding pad 184 is exposed.

The lower capping layer 190 may include a plurality of insulating layers. A portion of the lower capping layer 190 may be formed in each of processes of forming the lower interconnection structure 130 and the lower bonding structure 180. Accordingly, a first semiconductor structure S1, which is a peripheral circuit region PERI, may be formed. Since the process for the first semiconductor structure S1 is performed as a process different from the process for the second semiconductor structure S2, one of the processes may be performed preferentially or simultaneously.

The second semiconductor structure S2, which is a memory cell structure CELL, may be disposed upside down such that the base substrate 300 may be exposed to an upper portion, and the stack structure ST may be positioned below the base substrate 300, and the second semiconductor structure S2 may be bonded to the first semiconductor structure S1, which is a peripheral circuit structure PERI. The first semiconductor structure S1 and the second semiconductor structure S2 may be connected to each other by bonding the lower bonding pad 184 to the upper bonding pad 284 by applying pressure. The lower bonding insulating layer 186 and the upper bonding insulating layer 286 may be connected to each other by bonding by applying pressure. The second semiconductor structure S2 may be bonded to the first semiconductor structure S1 such that the upper bonding pad 284 may be directed downward. The first semiconductor structure S1 and the second semiconductor structure S2 may be directly bonded to each other without interposing an adhesive such as an adhesive layer.

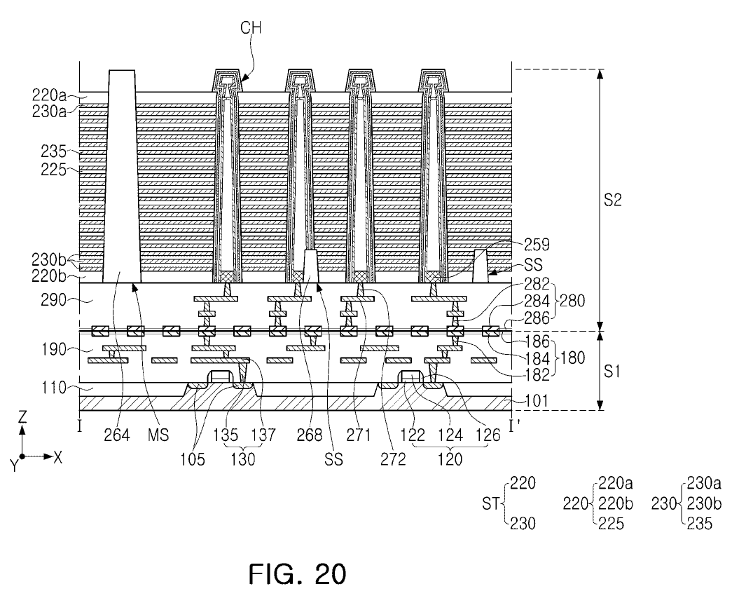

Referring to FIG. 20 together with FIG. 6, the base substrate 300 may be removed (S700).

The base substrate 300 may be removed, for example, by a polishing process such as a grinding process from an upper surface, and the other portion may be removed by an etching process such as wet etching. By removing the base substrate 300, the upper ends of the channel structures CH and the upper end of the isolation region MS may be exposed.

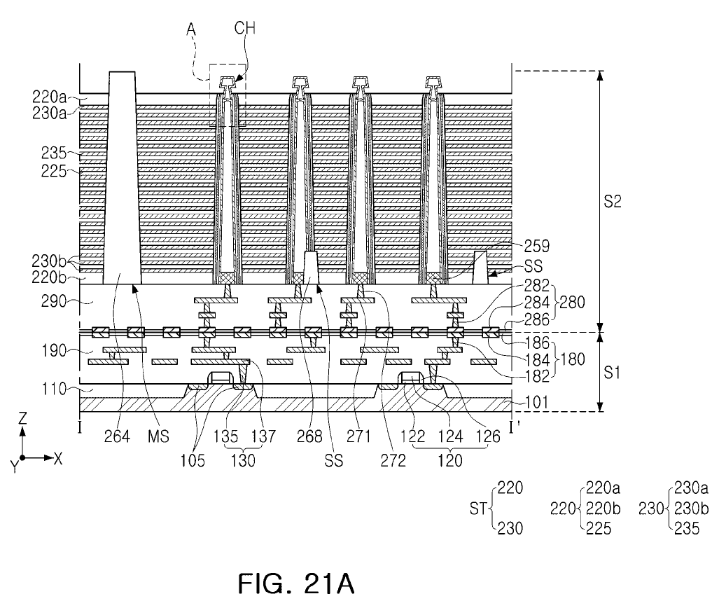

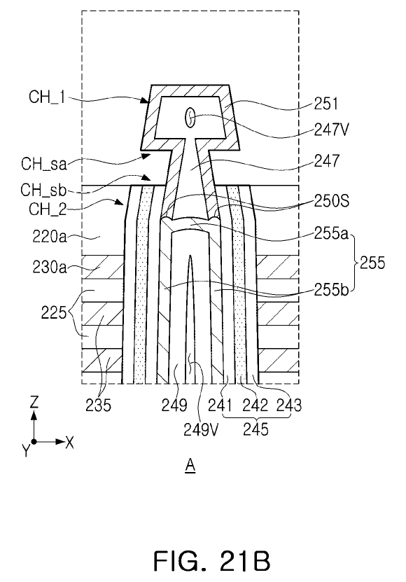

Referring to FIGS. 21A and 21B together with FIG. 6, by removing a portion of the data storage structure 245, the conductive spacer layer 251 may be exposed (S800).

The data storage structure 245 may be removed by a photolithography process and an etching process such as wet etching and/or dry etching. Accordingly, a portion of the conductive spacer layer 251 may be exposed. The channel structure CH may include a head portion CH_1 exposed to an upper surface of the first interlayer insulating layer 220a and a through-portion CH_2 extending into the stack structure ST. As a portion of the data storage structure 245 is removed, a first bent portion CH_sa and a second bent portion CH_sb of the channel structure CH may be formed.

Hereafter, referring to FIGS. 1A, 1B, 1C, and 1D together, a conductive layer CP may be formed (S900).

The conductive layer CP may be formed to cover the channel structures CH and the isolation regions MS protruding from an upper surface of the first interlayer insulating layer 220a and the first interlayer insulating layer 220a. The conductive layer CP may be formed by specifically depositing a crystalline silicon layer, for example, a polycrystalline silicon layer. Accordingly, the semiconductor device 10 in FIGS. 1A, 1B, 1C, and 1D may be manufactured.

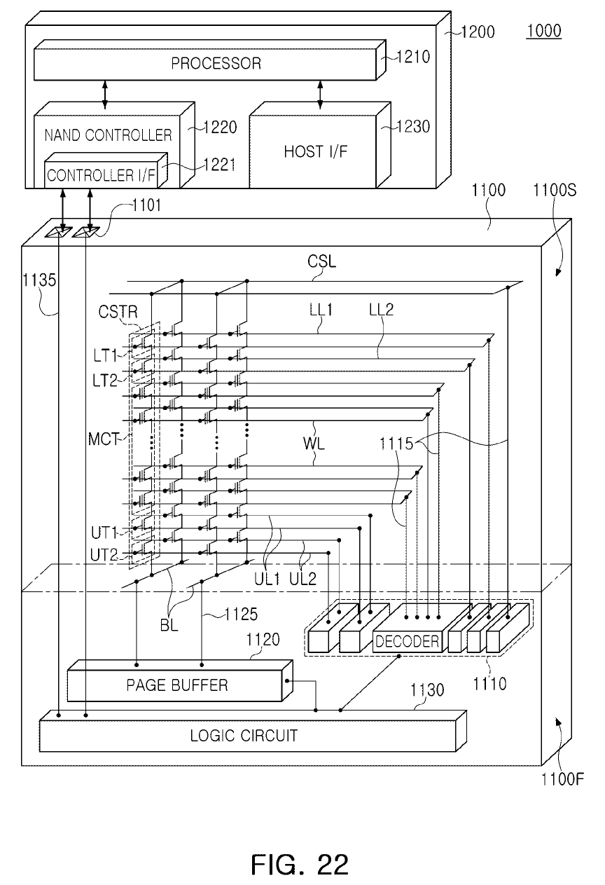

FIG. 22 is a diagram illustrating a data storage system including a semiconductor device according to example implementations.

Referring to FIG. 22, a data storage system 1000 may include a semiconductor device 1100 and a controller 1200 electrically connected to the semiconductor device 1100. The data storage system 1000 may be implemented as a storage device including one or a plurality of semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

The semiconductor device 1100 may be implemented as a non-volatile memory device, such as, for example, the NAND flash memory device described in the aforementioned example implementations with reference to FIGS. 1A, 1B, 1C, 1D, 2A, 2B, 3, 4, 5A and 5B. The semiconductor device 1100 may include a first structure 1100F and a second structure 1100S on the first structure 1100F. In the example implementations, the first structure 1100F may be disposed on the side of the second structure 1100S. The first structure 1100f may be configured as a peripheral circuit structure including a decoder circuit 1110, a page buffer 1120, and a logic circuit 1130. The second structure 1100S may be configured as a memory cell structure including a bitline BL, a common source line CSL, wordlines WL, first and second gate upper lines UL1 and UL2, first and second gate lower lines LL1 and LL2, and memory cell strings CSTR between the bitline BL and the common source line CSL.

In the second structure 1100S, each of the memory cell strings CSTR may include a plurality of memory cell transistors MCT disposed between lower transistors LT1 and LT2 adjacent to a common source line CSL, upper transistors UT1 and UT2 adjacent to a bitline BL, and lower transistors LT1 and LT2 and upper transistors UT1 and UT2. The number of lower transistors LT1 and LT2 and the number of upper transistors UT1 and UT2 may be varied in example implementations.

In example implementations, the upper transistors UT1 and UT2 may include string select transistors, and the lower transistors LT1 and LT2 may include ground select transistors. The gate lower lines LL1 and LL2 may be configured as gate electrodes of the lower transistors LT1 and LT2, respectively. The wordlines WL may be configured as gate electrodes 230 of the memory cell transistors MCT, and the gate upper lines UL1 and UL2 may be configured as gate electrodes of the upper transistors UT1 and UT2, respectively.

In example implementations, the lower transistors LT1 and LT2 may include a lower erase control transistor LT1 and a ground select transistor LT2 connected to each other in series. The upper transistors UT1 and UT2 may include a string select transistor UT1 and an upper erase control transistor UT2 connected to each other in series.

A common source line CSL, first and second gate lower lines LL1 and LL2, wordlines WL, and first and second gate upper lines UL1 and UL2 may be electrically connected to the decoder circuit 1110 through first interconnections 1115 extending from the first structure 1100f to the second structure 1100S. The bitlines BL may be electrically connected to the page buffer 1120 through the second interconnections 1125 extending from the first structure 1100f to the second structure 1100S.

In the first structure 1100f, the decoder circuit 1110 and the page buffer 1120 may perform a control operation for at least one select memory cell transistor among a plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output interconnection 1135 extending from the first structure 1100f to the second structure 1100S.

The controller 1200 may include a processor 1210, a NAND controller 1220, and a host interface 1230. In example implementations, the data storage system 1000 may include a plurality of semiconductor devices 1100, and in this case, the controller 1200 may control a plurality of semiconductor devices 1100.

The processor 1210 may control operations of the data storage system 1000 including the controller 1200. The processor 1210 may operate according to predetermined firmware and may access the semiconductor devices 1100 by controlling the NAND controller 1220. The NAND controller 1220 may include a controller interface 1221 handling communication with the semiconductor device 1100. Through the controller interface 1221, control commands for controlling the semiconductor device 1100, data to be written in the memory cell transistors MCT of the semiconductor device 1100, data to be read from the memory cell transistors MCT of the semiconductor device 1100, or the like, may be transmitted. The host interface 1230 may provide a communication function between the data storage system 1000 and an external host. When a control command is received from an external host through the host interface 1230, the processor 1210 may control the semiconductor device 1100 in response to the control command.

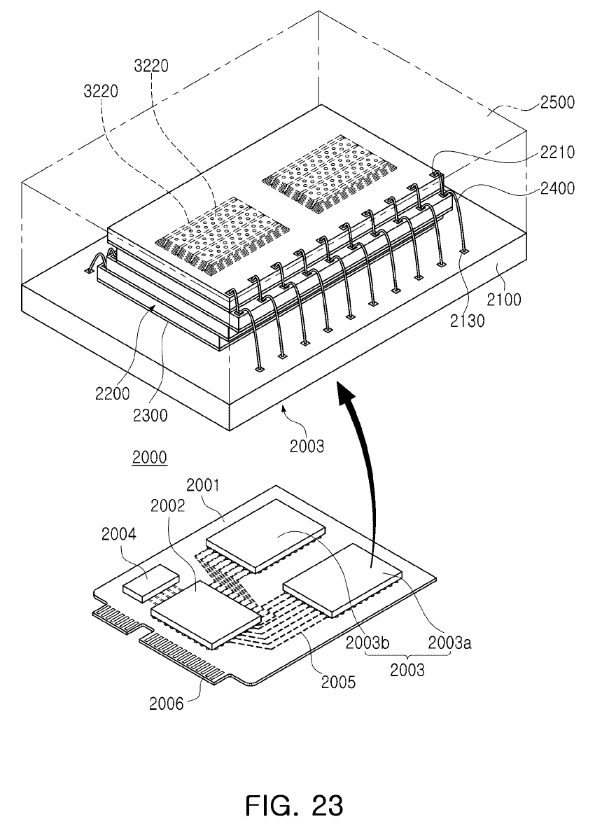

FIG. 23 is a perspective diagram illustrating a data storage system including a semiconductor device according to example implementations.

Referring to FIG. 23 a data storage system 2000 in some example implementations may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to an external host. The number and arrangement of the plurality of pins in the connector 2006 may be varied depending on a communication interface between the data storage system 2000 and the external host. In the example implementations, the data storage system 2000 may communicate with an external host according to one of interfaces from among universal serial bus (USB), peripheral component interconnect express (PCI-Express), serial advanced technology attachment (SATA), M-Phy for universal flash storage (UFS). In the example implementations, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or may read data from the semiconductor package 2003, and may improve an operating speed of the data storage system 2000.

The DRAM 2004 may be configured as a buffer memory for alleviating a difference in speeds between the semiconductor package 2003, which is a data storage space, and an external host. The DRAM 2004 included in the data storage system 2000 may operate as a cache memory, and may provide a space for temporarily storing data in a control operation for the semiconductor package 2003. When the data storage system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be configured as a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of the semiconductor chips 2200, respectively, a bonding structure 2400 electrically connecting the semiconductor chips 2200 to the package substrate 2100, and a molding layer 2500 covering the semiconductor chips 2200 and the bonding structure 2400 on the package substrate 2100.

The package substrate 2100 may be configured as a printed circuit board including package upper pads 2130. Each semiconductor chip 2200 may include an input/output pad 2210. The input/output pad 2210 may correspond to the input/output pad 1101 in FIG. 23. Each of the semiconductor chips 2200 may include gate stack structures 3210 and channel structures 3220. Each of the semiconductor chips 2200 may include the semiconductor device described in the aforementioned example implementations with reference to FIGS. 1A, 1B, 1C, 1D, 2A, 2B, 3, 4, 5A, and 5B.

In the example implementations, the bonding structure 2400 may be configured as a bonding wire electrically connecting the input/output pad 2210 to the upper package pads 2130. Accordingly, in each of the first and second semiconductor packages 2003a and 2003b, the semiconductor chips 2200 may be electrically connected to each other by a bonding wire method, and may be electrically connected to the upper pads 2130 of the package substrate 2100. In the example implementations, in each of the first and second semiconductor packages 2003a and 2003b, the semiconductor chips 2200 may be electrically connected to each other by a connection structure including a through-electrode (TSV) instead of the bonding structure 2400 of a bonding wire method.

In the example implementations, the controller 2002 and the semiconductor chips 2200 may be included in a single package. In some example implementations, the controller 2002 and the semiconductor chips 2200 may be mounted on an interposer substrate different from the main board 2001, and the controller 2002 and the semiconductor chips 2200 may be connected to each other by interconnection formed on the interposer substrate.

According to the aforementioned example implementations, in a structure in which two or more semiconductor structures are bonded to each other, the channel structure may include a conductive spacer layer in contact with the conductive layer, and a channel layer extending into gate electrodes and interlayer insulating layers. The channel layer may include a folded portion positioned at a level at which the conductive layer overlaps the most adjacent first interlayer insulating layer among the interlayer insulating layers, thereby preventing a defect occurring in the conductive spacer layer during a process. Accordingly, a semiconductor device having improved integration density and reliability and a data storage system including the same may be provided.

According to example implementations of the present disclosure, a method of manufacturing a semiconductor device includes preparing a base substrate including an etching stop structure on an upper surface; forming a mold structure by alternately stacking interlayer insulating layers and sacrificial insulating layers on the base substrate; penetrating the mold structure, exposing the etching stop structures, and forming a channel hole including a head portion by removing the etching stop structures; forming a data storage structure in the channel hole; forming a conductive spacer layer on the data storage structure and a first buried insulating layer on the conductive spacer layer in the head portion; and forming a channel layer covering the data storage structure, the conductive spacer layer and the first buried insulating layer, and a second buried insulating layer on the channel layer.

The channel layer and the conductive spacer layer have different crystal structures.

The channel layer has a monocrystalline structure, and the conductive spacer layer has a polycrystalline structure.

The channel layer and the conductive spacer layer have a crystalline structure, and a grain size of the channel layer is greater than a grain size of the conductive spacer layer.

The grain size of the channel layer is at least 5 times greater than the grain size of the conductive spacer layer.

The method further comprising: crystallizing the channel layer, the crystallizing the channel layer is performed by a metal induced lateral crystallization (MILC) process.

The method further includes crystallizing the channel layer before the forming the channel layer, and the crystallizing a conductive spacer layer is performed by an annealing process at 500°C or higher.

The method further comprising: crystallizing the channel layer, wherein the crystallizing the channel layer is performed by an annealing process at 500°C or higher.

The method further comprising: removing the base substrate, removing a portion of the data storage structure and exposing the conductive spacer layer.

The method further includes forming a conductive layer covering the conductive spacer layer after the exposing the conductive spacer layer.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the example implementations have been illustrated and described above, it will be configured as apparent to those skilled in the art that modifications and variations could be made without departing from the scope of the present disclosure as defined by the appended claims.

What is claimed is:

1. A semiconductor device, comprising:
a first semiconductor structure including a first substrate, circuit elements on the first substrate, a lower interconnection structure connected to the circuit elements, and a lower bonding structure connected to the lower interconnection structure; and
a second semiconductor structure connected to the first semiconductor structure on the first semiconductor structure,
wherein the second semiconductor structure includes
a conductive layer,
a stack structure below the conductive layer and including interlayer insulating layers and gate electrodes stacked in a first direction perpendicular to a lower surface of the conductive layer,
an upper interconnection structure below the stack structure,
an upper bonding structure connected to the upper interconnection structure and bonded to the lower bonding structure, and
channel structures extending into the stack structure in the first direction and protruding to an upper surface of the stack structure,
wherein each of the channel structures includes a through-portion extending into the stack structure and a head portion protruding to the upper surface of the stack structure,
wherein each of the channel structures includes
a conductive spacer layer forming an outer region of the head portion and being in contact with the conductive layer,
a first buried insulating layer on an internal side surface of the conductive spacer layer,
a channel layer in the through-portion and including a folded portion covering a lower surface of the first buried insulating layer and a channel portion extending in the first direction from a lower end of the conductive spacer layer,
a second buried insulating layer on an internal side surface of the channel layer and spaced apart from the first buried insulating layer, and
a data storage structure on an external side surface of the channel layer.

2. The semiconductor device of claim 1, wherein the channel layer and the conductive spacer layer have different crystal structures.

3. The semiconductor device of claim 1,
wherein the channel layer has a monocrystalline structure, and
wherein the conductive spacer layer has a polycrystalline structure.

4. The semiconductor device of claim 1,
wherein the channel layer and the conductive spacer layer have a crystalline structure, and
wherein a grain size of the channel layer is greater than a grain size of the conductive spacer layer.

5. The semiconductor device of claim 4, wherein the grain size of the channel layer is at least five times greater than the grain size of the conductive spacer layer.

6. The semiconductor device of claim 1, wherein the conductive spacer layer and the conductive layer include a semiconductor material including first conductivity-type impurities.

7. The semiconductor device of claim 6, wherein a concentration of the first conductivity-type impurities of the conductive spacer layer is greater than a concentration of first conductivity-type impurities of the channel layer.

8. The semiconductor device of claim 1,
wherein the stack structure includes an uppermost interlayer insulating layer on a lower surface of the conductive layer, and
wherein the folded portion of the channel layer overlaps the uppermost interlayer insulating layer in a direction perpendicular to the first direction.

9. The semiconductor device of claim 1, wherein the data storage structure covers a portion of an external side surface of the conductive spacer layer.

10. The semiconductor device of claim 1, wherein, in each of the channel structures, a thickness of the conductive spacer layer is less than a thickness of the channel layer.

11. The semiconductor device of claim 1, wherein at least a portion of the channel structures includes a first void in the first buried insulating layer.

12. The semiconductor device of claim 1,
wherein the stack structure includes an uppermost interlayer insulating layer on a lower surface of the conductive layer, and
wherein a boundary surface between the conductive spacer layer and the channel layer overlaps the uppermost interlayer insulating layer in a direction perpendicular to the first direction.

13. The semiconductor device of claim 1, wherein an upper end of the data storage structure is positioned higher than an upper end of the channel layer.

14. A semiconductor device, comprising:
gate electrodes spaced apart from each other in a first direction, the gate electrodes including an uppermost gate electrode;
channel structures extending in the first direction and extending into the gate electrodes, each including a channel layer, a channel filling insulating layer on an internal side surface of the channel layer, a data storage structure on an external side surface of the channel layer, and a conductive spacer layer on the channel layer; and
a conductive layer in contact with the conductive spacer layer of the channel structures on the uppermost gate electrode,
wherein the channel layer of each of the channel structures includes
a channel portion extending in the first direction, and
a folded portion bent from the channel portion at a higher level than an upper surface of the uppermost gate electrode and covering an upper end of the channel filling insulating layer, and
wherein, in a planar view parallel to a lower surface of the conductive layer, a minimum width of the channel layer is greater than a minimum width of the conductive spacer layer and is less than a maximum width of the conductive spacer layer.

15. The semiconductor device of claim 14,
wherein each of the channel structures includes bent portions formed by a step difference in width, and
wherein the bent portions include a first bent portion positioned at a level overlapping the conductive layer, and a second bent portion positioned at a level lower than a level of the first bent portion and higher than a level of an upper surface of the uppermost gate electrode.

16. The semiconductor device of claim 15,
wherein each of the channel structures includes a through-portion extending into the gate electrodes and a head portion protruding into the conductive layer, and
wherein the second bent portion is between the through-portion and the head portion.

17. The semiconductor device of claim 14, wherein, in the planar view, the folded portion has a circular shape, an elliptical shape or a polygonal shape, and the data storage structure surrounds the folded portion.

18. The semiconductor device of claim 14, wherein, in the planar view, the channel portion surrounds the channel filling insulating layer at a lower level than the folded portion.

19. The semiconductor device of claim 14, wherein an upper surface of the folded portion has an outwardly curved shape protruding toward the conductive layer.

20. A data storage system, comprising:
a semiconductor storage device including a first semiconductor structure including a substrate and circuit elements on the substrate, a second semiconductor structure on the first semiconductor structure, and input/output pads electrically connected to the circuit elements; and
a controller electrically connected to the semiconductor storage device through the input/output pads and controlling the semiconductor storage device,
wherein the second semiconductor structure includes
a conductive layer,
a stack structure below the conductive layer and including interlayer insulating layers and gate electrodes stacked in a first direction perpendicular to a lower surface of the conductive layer, and
channel structures extending into the stack structure in the first direction and protruding to an upper surface of the stack structure,
wherein each of the channel structures includes a through-portion extending into the stack structure and a head portion protruding to the upper surface of the stack structure,
wherein each of the channel structures includes
a conductive spacer layer defining an outer region of the head portion and being in contact with the conductive layer,
a first buried insulating layer on an internal side surface of the conductive spacer layer,
a channel layer in the through-portion and including a folded portion covering a lower surface of the first buried insulating layer and a channel portion extending in the first direction from a lower end of the conductive spacer layer,
a second buried insulating layer on an internal side surface of the channel layer and spaced apart from the first buried insulating layer, and
a data storage structure on an external side surface of the channel layer.
